(19) United States
(12) Patent Application Publication
(10) Pub. No.: US 2020/0312890 A1
(43) Pub. Date: Oct. 1, 2020

(54) ELECTRO-OPTICAL DEVICE AND ELECTRONIC APPARATUS

(71) Applicant: SEIKO EPSON CORPORATION, Tokyo (JP)

(72) Inventors: Hiroyuki OIKAWA, Chitose-shi (JP); Toru NIMURA, Matsumoto-shi (JP); Shinsuke FUJIKAWA, Chino-shi (JP)

(73) Assignee: SEIKO EPSON CORPORATION, Tokyo (JP)

(21) Appl. No.: 16/829,391

(22) Filed: Mar. 25, 2020

(30) Foreign Application Priority Data
Mar. 26, 2019 (JP) 2019-057881

(51) Int. Cl. H01L 27/12

(52) U.S. Cl. CPC H01L 27/1248; H01L 27/124

(57) ABSTRACT

In the electro-optical device, a gate electrode and a scanning line are electrically connected through a first contact hole disposed on the first insulating layer (interlayer insulating layer) overlapping the transistor. In a layer between the gate electrode and the scanning line, a first light shielding layer to which a constant potential is applied is disposed, and a light shielding portion electrically connected to the first light shielding layer covers a part of the semiconductor layer from both sides in a width direction. The light shielding portion includes a first portion that electrically connects the second light shielding layer and the first light shielding layer, and a second portion protruding from the first portion toward the semiconductor layer.

### ELECTRO-OPTICAL DEVICE AND ELECTRONIC APPARATUS

The present application is based on, and claims priority from JP Application Serial Number 2019-057881, filed Mar. 26, 2019, the disclosure of which is hereby incorporated by reference herein in its entirety.

### BACKGROUND

### 1. Technical Field

The present disclosure relates to an electro-optical device provided with a transistor, and an electronic apparatus.

### 2. Related Art

In electro-optical devices such as liquid crystal devices and the like, when light is incident on a pixel electrode side source/drain region of the transistor, there is a problem that the transistor characteristics are reduced due to photocurrent. On the other hand, a configuration has been proposed in which a scanning line coupled, through a contact hole, to a gate electrode of the transistor from an upper layer side overlaps the pixel electrode side source/drain region with a thin insulating layer interposed therebetween (see JP-A-2015-7806).

In an aspect described in JP-A-2015-7806, the scanning line overlaps the pixel electrode side source/drain region, and thus the scanning line can be used as a light shielding layer. However, because the scanning line overlaps the pixel electrode side source/drain region with the thin insulating layer interposed therebetween, there is a problem that an influence of a potential of a scanning signal supplied to the scanning line is easily to reach between a channel region and a drain region. More specifically, even when a negative off potential is supplied from the scanning line to the gate potential, when the potential of the scanning line affects between the channel region and the drain region, leakage current of the transistor jumps up greatly. Such a problem, in the drain region, even when a low concentration impurity region is disposed in a region overlapping an end of the gate, cannot be sufficiently suppressed. On the other hand, when the insulating layer interposed between the scanning line and the pixel electrode side source/drain region is thickened, light traveling in from an oblique direction is incident on the pixel electrode side source/drain region with a thick insulating layer interposed therebetween. Therefore, in the configuration described in JP-A-2015-7806, there is a problem that it is difficult to suppress light from being incident on a semiconductor layer while suppressing the influence of the potential of the scanning signal supplied to the scanning line from excessively affecting the semiconductor layer.

### SUMMARY

In order to solve the above-described problem, an aspect of the electro-optical device according to the present disclosure includes: a transistor having a gate electrode and a semiconductor layer, a first insulating layer overlapping the transistor and having a first contact hole, a scanning line electrically connected to the gate electrode through the first contact hole, a first light shielding layer, that is disposed at a layer between the gate electrode and the scanning line, and to which a constant potential is applied, and a light shielding portion that is disposed to cover a part of the semiconductor layer and that is electrically connected to the first light shielding layer.

The electro-optical device according to the present disclosure is used for a variety of electronic apparatuses. In the present disclosure, when the electro-optical device is used for a projection-type display device of electronic apparatuses, the projection-type display device is provided with a light-source unit configured to emit a light to be supplied to the electro-optical device, and a projection optical system configured to project light modulated by the electro-optical device.

### BRIEF DESCRIPTION OF THE DRAWINGS

FIG. 1 is a plan view illustrating one aspect of an electro-optical device according to Exemplary Embodiment 1 of the present disclosure.

FIG. 2 is a cross-sectional view of the electro-optical device illustrated in FIG. 1.

FIG. 3 is a block diagram illustrating the electrical configuration of the electro-optical device illustrated in FIG. 1.

FIG. 4 is a plan view of a plurality of pixels adjacent to each other in the electro-optical device illustrated in FIG. 1.

FIG. 5 is an enlarged plan view illustrating one of a periphery of a transistor illustrated in FIG. 4.

FIG. 6 is an A-A′ cross-sectional view of the transistor illustrated in FIG. 5.

FIG. 7 is a B-B′ cross-sectional view of the transistor illustrated in FIG. 5.

FIG. 8 is a C-C′ cross-sectional view illustrating a connection structure of a gate electrode and a fourth light shielding layer illustrated in FIG. 5.

FIG. 9 is a plan view of a semiconductor layer, a third light shielding layer, the fourth light shielding layer, and the like illustrated in FIG. 5.

FIG. 10 is a plan view of the fourth light shielding layer, a gate electrode, a scanning line, and the like illustrated in FIG. 5.

FIG. 11 is a plan view of the third light shielding layer, a first light shielding layer, a second light shielding layer, and the like illustrated in FIG. 5.

FIG. 12 is a plan view of a first capacitor electrode, a second capacitor electrode, and the like illustrated in FIG. 5.

FIG. 13 is a plan view of the second capacitor electrode, a third capacitor electrode, and the like illustrated in FIG. 5.

FIG. 14 is a plan view of a data line and the like illustrated in FIG. 5.

FIG. 15 is a plan view of a capacitance line and the like illustrated in FIG. 5.

FIG. 16 is an explanatory diagram of an electro-optical device according to embodiment 2 of the present disclosure.

FIG. 17 is a D-D′ cross-sectional view of the transistor illustrated in FIG. 16.

FIG. 18 is an E-E′ cross-sectional view of the transistor illustrated in FIG. 16.

FIG. 19 is a plan view of the semiconductor layer, the fourth light shielding layer, and the like illustrated in FIG. 16.

FIG. 20 is a plan view of the fourth light shielding layer, a gate electrode, a scanning line, and the like illustrated in FIG. 16.

FIG. 21 is a plan view of the first light shielding layer, the second light shielding layer illustrated in FIG. 16.

FIG. 22 is a plan view of the first capacitor electrode, the second capacitor electrode, and the like illustrated in FIG. 16.

FIG. 23 is a plan view of the second capacitor electrode, the third capacitor electrodes, and the like illustrated in FIG. 16.

FIG. 24 is a plan view of the data line and the like illustrated in FIG. 16.

FIG. 25 is a plan view of the capacitance line and the like illustrated in FIG. 16.

FIG. 26 is a schematic configuration diagram of a projection-type display device (an electronic apparatus) using the electro-optical device to which the present disclosure is applied.

### DESCRIPTION OF EXEMPLARY EMBODIMENTS

Exemplary embodiments of the disclosure will be described below with reference to the figures. Note that, in each of the figures to be referred to in the following description, to illustrate each layer, each member, and the like in a recognizable size in the drawings, each layer, each member, and the like are illustrated at a different scale. In addition, in the following description, in an in-plane direction of a first substrate 19, two directions intersecting with each other will be described as an X-axis direction and a Y-axis direction. Further, when describing layers formed on an element substrate 10, an upper layer side or a surface side refers to a side (a second substrate 29 side) opposite to a first substrate 19 side, and a lower surface side refers to the first substrate 19 side.

### Embodiment 1

### Configuration of Electro-Optical Device

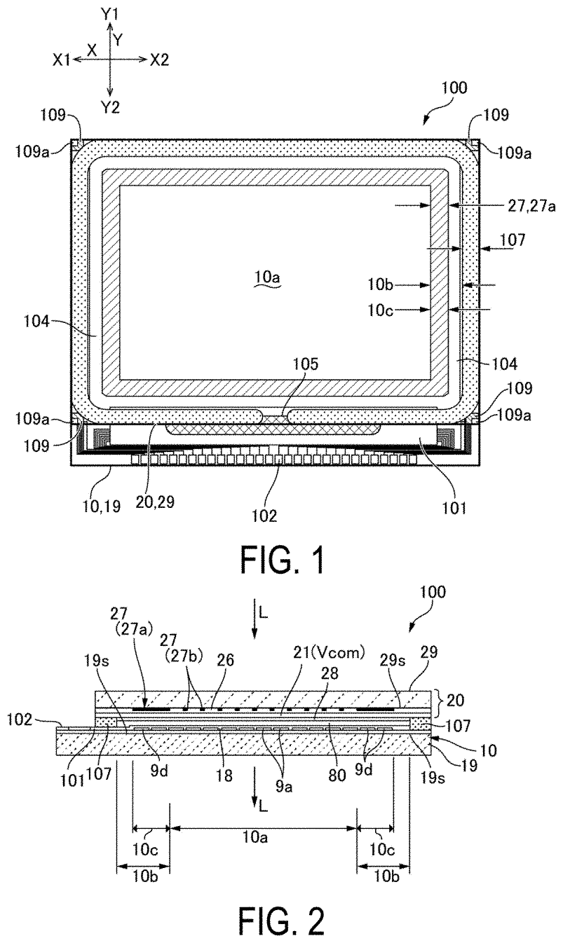

FIG. 1 is a plan view illustrating one aspect of an electro-optical device 100 according to Exemplary Embodiment 1 of the present disclosure. FIG. 2 is a cross-sectional view of the electro-optical device 100 illustrated in FIG. 1. As illustrated in FIG. 1 and FIG. 2, in the electro-optical device 100, a first substrate 19 and a second substrate 29 are bonded together through a sealing material 107 with a predetermined gap, and the first substrate 19 is opposed to the second substrate 29. The sealing material 107 is disposed in a frame-like shape in conformance with the outer edge of the second substrate 20, an electro-optical layer 80 such as a liquid crystal layer is arranged in an area surrounded by the sealing material 107 between the first substrate 19 and the second substrate 29. Accordingly, the electro-optical device 100 is configured as a liquid crystal device. The seal material 107 is a photocurable adhesive, or a photocurable and thermosetting adhesive, and the seal material 107 is compounded in a gap material such as glass fiber or glass beads for setting a distance between the two substrates to a predetermined value. The first substrate 19 and the second substrate 29 are both a quadrangle, and in a substantially central of the electro-optical device 100, a display region 10a is disposed as a quadrangular region. In accordance with such a shape, the seal material 107 is also disposed in a substantially quadrangular shape, and a peripheral region 10b having a rectangular frame shape is disposed between an inner peripheral edge of the seal material 107 and an outer peripheral edge of the display region 10a.

The first substrate 19, as a substrate body of an element substrate 10, includes a translucent substrate such as a quartz substrate or a glass substrate. In one surface 19s of the first substrate 19 at the second substrate 29 side, in the outside of the display region 10a, a data line driving circuit 101 and a plurality of terminals 102 are formed along one side of the first substrate 19, and a scanning line driving circuit 104 is formed along the other side adjacent to this one side. A flexible wiring substrate (not illustrated) is coupled to the terminals 102, and various potentials and various signals are input to the first substrate 19 via the flexible wiring substrate.

In the one surface 19s of the first substrate 19, in the display region 10a, a plurality of pixel electrodes 9a which have translucency and which are formed of an Indium Tin Oxide (ITO) film and the like, and transistors (not illustrated in FIG. 1 and FIG. 2) electrically coupled to each of the plurality of pixel electrodes 9a are formed in a matrix shape. A first alignment film 18 is formed at the second substrate 29 side with respect to the pixel electrodes 9a, and the pixel electrodes 9a are covered with the first alignment film 18.

The second substrate 29, as a substrate body of a counter substrate, includes a translucent substrate such as a quartz substrate or a glass substrate. On one surface 29s side facing the first substrate 19 in the second substrate 29, a common electrode 21 which has translucency and which is formed of the ITO film or the like is formed, and on the first substrate 19 side with respect to the common electrode 21, a second alignment film 26 is formed. The common electrode 21 is formed over substantially the entire surface of the second substrate 29 and covered with the second alignment film 28. On the one surface 29s side of the second substrate 29, on the opposite side of the first substrate 19 with respect to the common electrode 21, a light shielding layer 27 which has light shielding property and which is formed of resin, metal, or metal compound is formed, a protective layer 26 having translucency is formed between the light shielding layer 27 and the common electrode 21. The light shielding layer 27 is formed, for example, as a partition 27a in a frame-like shape extending along the outer peripheral edge of the display region 10a. The light shielding layer 27 may be occasionally formed as a light shielding layer 27b (black matrix) in a region overlapping in plan view with a region interposed between the pixel electrodes 9a adjacent to each other. In the peripheral region 10b of the first substrate 19, in the dummy pixel area 10c overlapping in plan view with the partition 27a, a dummy pixel region 9d, which is concurrently formed with the pixel electrodes 9a, is formed.

The first alignment film 18 and the second alignment film 28 are inorganic alignment films formed of obliquely vapor-deposited film of SiOₓ (x<2), SiO₂, TiO₂, MgO, Al₂O₃, and the like, and liquid crystal molecules having negative dielectric anisotropy used for the electro-optical layer 80 are tilt-aligned. Therefore, the liquid crystal molecules form a predetermined angle with respect to the first substrate 19 and the second substrate 29. In this way, the electro-optical device 100 is configured as a liquid crystal device of a Vertical Alignment (VA) mode.

In the first substrate 19, in a region overlapping a corner portion of the second substrate 29 outside the sealing material 107, an inter-substrate conduction electrode 109 is formed so that electrical conduction is established between the first substrate 19 and the second substrate 29. In the inter-substrate conduction electrode 109, an inter-substrate conduction material 109a including conductive particle is arranged, the common electrode 21 of the second substrate 29 is electrically coupled to the first substrate 19 side via the inter-substrate conduction material 109a and the inter-substrate conduction electrode 109. Thus, the common potential Vcom is applied to the common electrode 21 from the side of the first substrate 19.

In the electro-optical device 100 of the present embodiment, the pixel electrodes 9a and the common electrode 21 are formed of an ITO film, and the electro-optical device 100 is configured as a transmissive liquid crystal device. In such an electro-optical device 100, in the first substrate 19 and the second substrate 29, light that is incident to the electro-optical layer 80 from either one of the substrates is modulated while extending through the other substrate and being emitted, and displays an image. In the present embodiment, as indicated by an arrow L, the light that is incident from the second substrate 29 is modulated by the electro-optical layer 80 for each pixel while extending through the first substrate 19 and being emitted, and displays an image. Note that, In the electro-optical device 100, the light that is incident from the first substrate 19 may be occasionally modulated by the electro-optical layer 80 for each pixel while extending through the second substrate 29 and being emitted, and displays an image.

Electrical Configuration of Electro-Optical Device 100

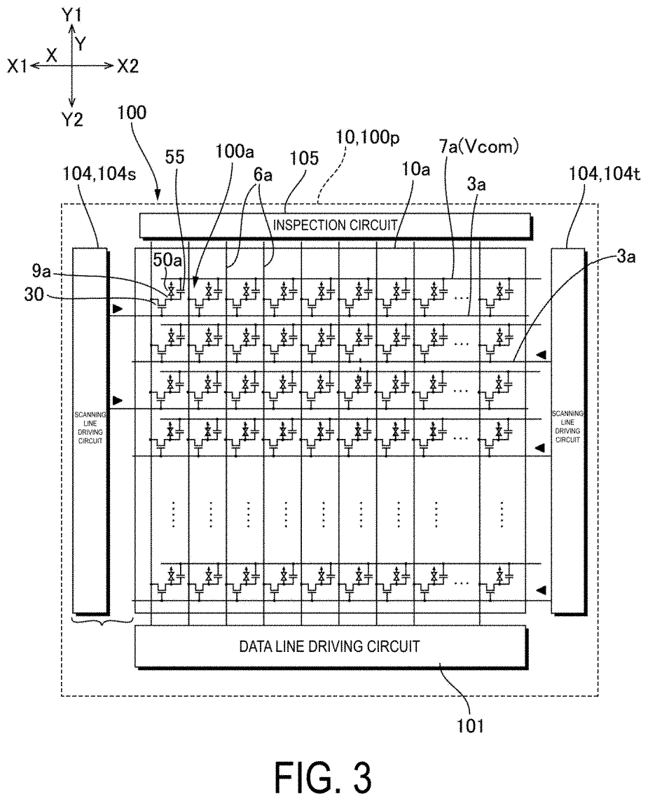

FIG. 3 is a block diagram illustrating the electrical configuration of the electro-optical device 100 illustrated in FIG. 1. In FIG. 3, the electro-optical device 100 is provided with a VA mode liquid crystal panel 100p, and the liquid crystal panel 100p includes the display region 10a in which a plurality of pixels 100a are arranged in a matrix pattern in a central region. In the liquid crystal panel 100p, in the first substrate 19 described above with reference to FIG. 1, FIG. 2 and the like, a plurality of scanning lines 3a extending in the X-axis direction and a plurality of data lines 6a extending in Y-axis direction are formed on the inner side of the display region 10a, the plurality of pixels 100a are configured to correspond to each of intersections between the plurality of scanning lines 3a and the plurality of data lines 6a. The plurality of scanning lines 3a is electrically coupled to the scanning line driving circuits 104 and the plurality of data lines 6a is coupled to the data line driving circuit 101. An inspection circuit 105 is electrically coupled to the plurality of data lines 6a on the opposite side of the data line drive circuit 101 in the Y-axis direction.

In each of the plurality of pixels 100a, a transistor 30 for pixel switching formed of a field effect transistor or the like, and the pixel electrode 9a electrically coupled to the transistor 30, are formed. The data line 6a is electrically coupled to the source of the transistor 30, the scanning line 3a is electrically coupled to the gate of the transistor 30, and the pixel electrode 9a is electrically coupled to the drain of the transistor 30. An image signal is supplied to the data line 6a, and a scanning signal is supplied to the scanning line 3a. In the present embodiment, the scanning line drive circuits 104 are configured as a scanning line drive circuit 104s and 104t on an one side X1 and another side X2 in the X-axis direction of the display area 10a, the scanning line drive circuit 104s on the one side X1 in the X-axis direction drives the odd-numbered scanning lines 3a and the scanning line drive circuit 104t on the other side X2 in the X-axis direction drives the even-numbered scanning lines 3a.

In each of the pixels 100a, the pixel electrode 9a, which faces the common electrode 21 of the second substrate 29 described above with reference to FIG. 1 and FIG. 2 with the electro-optical layer 80 interposed therebetween, configures a liquid crystal capacitor 50a. A holding capacitor 55 disposed in parallel with the liquid crystal capacitor 50a is added to each pixel 100a to prevent fluctuations of the image signal held by the liquid crystal capacitor 50a. In the present embodiment, in order to configure the holding capacitors 55, capacitance lines 7a extending across the plurality of pixels 100a are formed in the first substrate 19, and a common potential Vcom is supplied to the capacitance lines 7a. In FIG. 3, although one capacitance line 7a is illustrated extending in the X-axis direction, the capacitance line 7a may be extended in the Y-axis direction, and may also be extended in both the X-axis direction and the Y-axis direction.

Overview Configuration of Pixel 100a

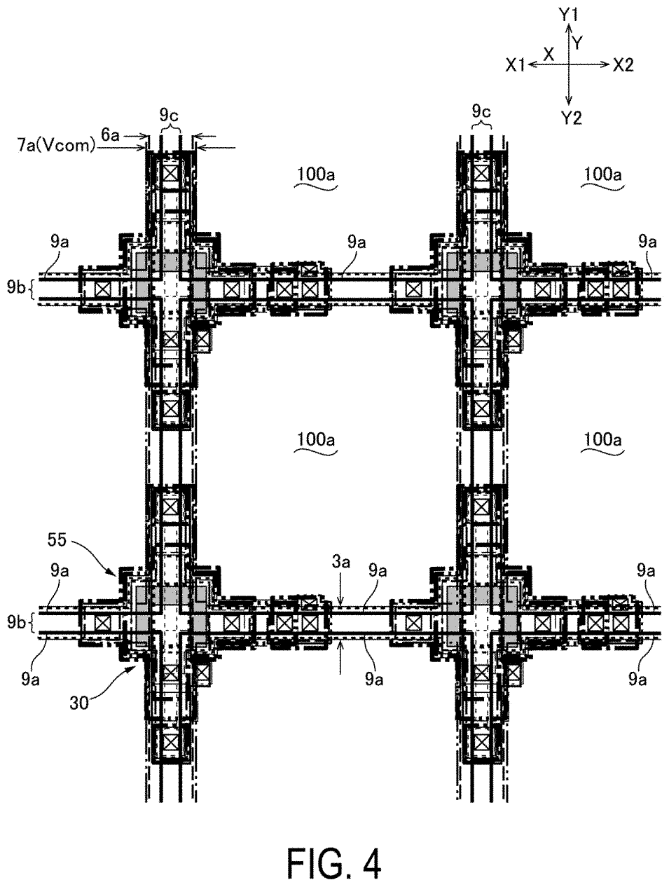

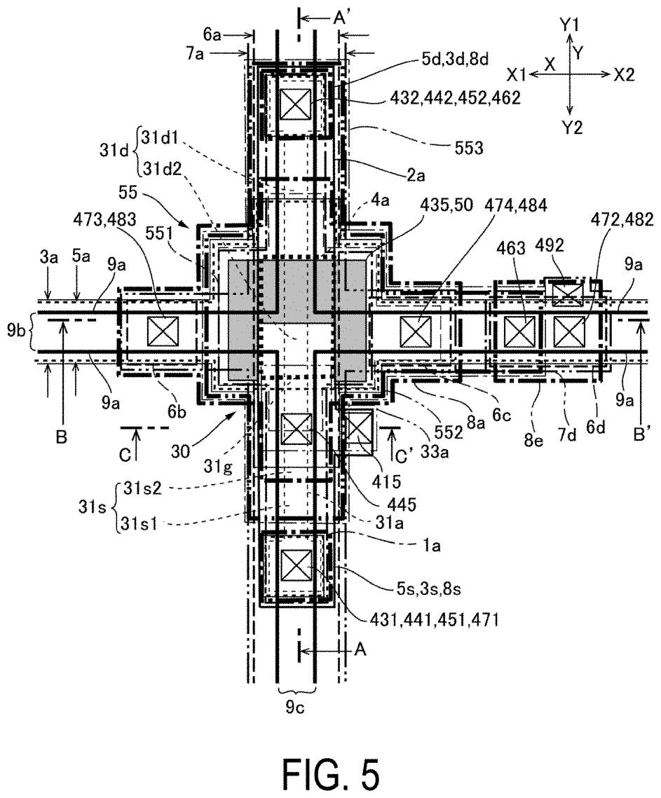

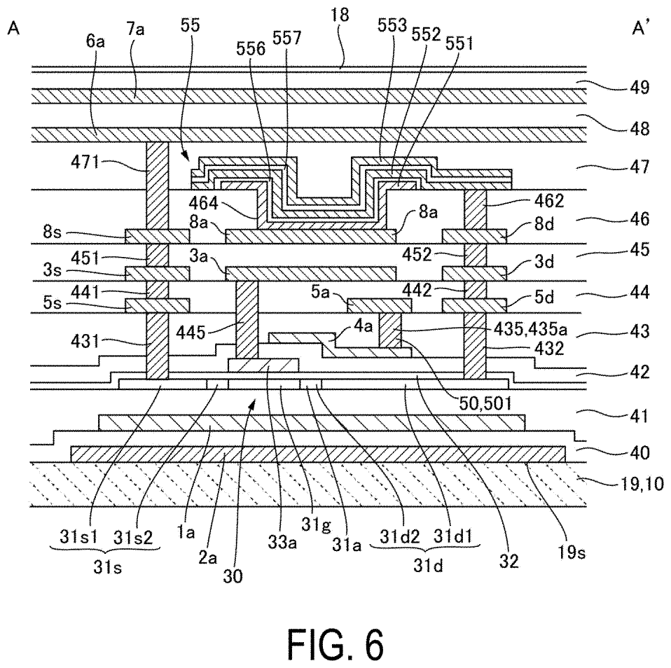

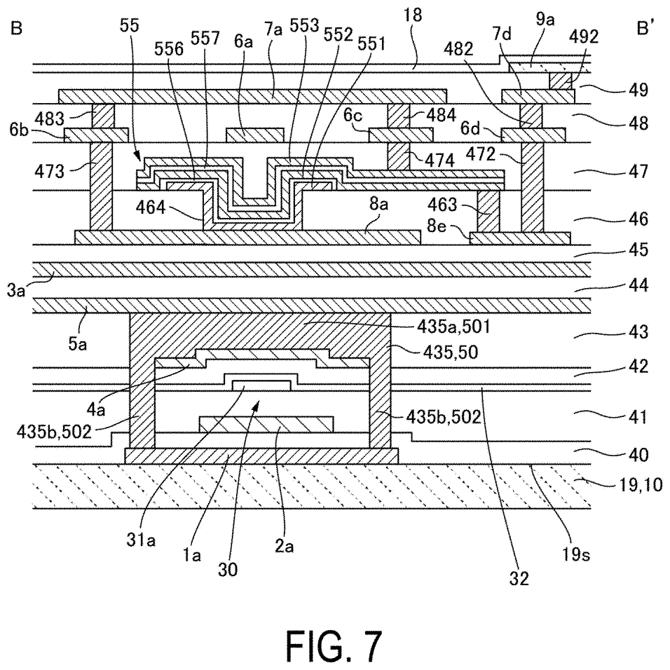

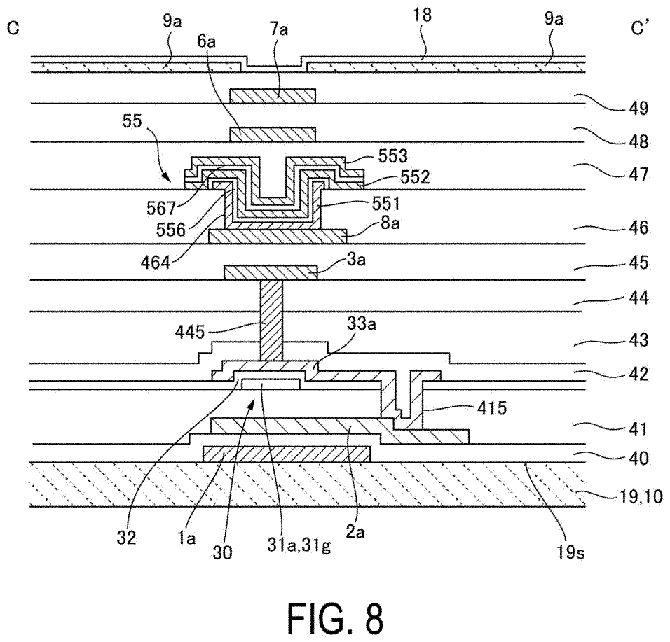

FIG. 4 is a plan view of the plurality of pixels 100a adjacent to each other in the electro-optical device 100 illustrated in FIG. 1. FIG. 5 is an enlarged plan view illustrating one of the periphery of the transistor 30 illustrated in FIG. 4. FIG. 6 is the A-A′ cross-sectional view of the transistor 30 illustrated in FIG. 5, and is a cross-sectional view schematically illustrating a case of cutting along the semiconductor layer 31a. FIG. 7 is the B-B′ cross-sectional view of the transistor 30 illustrated in FIG. 5, and is a cross-sectional view schematically illustrating a case of cutting along the scanning line 3a. FIG. 8 is a C-C′ cross-sectional view illustrating a connection structure of a gate electrode 33a and a fourth light shielding layer 2a illustrated in FIG. 5, and is a cross-sectional view schematically illustrating a case of cutting along the scanning line 3a at a position through a contact hole 415 coupling a gate electrode 33a and the fourth light shielding layer 2a. Note that, FIG. 7 also illustrates a contact hole 492 electrically coupling the pixel electrode 9a and a relay electrode 7a. FIG. 4 and FIG. 5 and FIG. 9 to FIG. 13 described below, the layers are represented by the following lines. Further note that in FIG. 4 and FIG. 5 and FIG. 9 to FIG. 13 described below, for the layers in which the end portions overlap with each other in plan view, the end portions are shifted so that the shape and the like of the layers are easily recognizable.

Third light shielding layer 1a is represented by medium-thickness dot-dash line.

Fourth light shielding layer 2a is represented by medium-thickness solid line.

Semiconductor layer 31a is represented by very thin short dashed line.

Gate electrode 33a is represented by very thin two-dot chain line.

First light shielding layer 4a is represented by very thick short dashed line.

Second light shielding layer 5a is represented by medium-thickness short dashed line.

Scanning line 3a is represented by very thin solid line.

Relay electrode 8a is represented by very thick dot-dash line.

First capacitor electrode 551 is represented by very thin long dashed line.

Second capacitance electrode 552 is represented by very thick two-dot chain line.

Third capacitance electrode 553 is represented by very thin dot chain line.

Data line 6a is represented by medium-thickness long dashed line.

Capacitance line 7a is represented by medium-thickness two-dot chain line.

Pixel electrode 9a is represented by very thick solid line.

As illustrated in FIG. 4 and FIG. 5, on the surface of the first substrate 19 facing the counter substrate 29, the pixel electrode 9a is formed in each of the plurality of pixels 100a, and the scanning line 3a, the data line 6a, and a capacitor line 7a extend along the inter-pixel region sandwiched between the pixel electrodes 9a adjacent to each other. More specifically, the scanning line 3a extends in the X-axis direction overlapping the first inter-pixel region 9b extending in the X-axis direction, and the data line 6a and the capacitor line 7a extend in the Y-axis direction overlapping the second inter-pixel region 9c extending in the Y-axis direction. The transistor 30 is formed corresponding to the intersection between the data line 6a and the scanning line 3a. The scanning line 3a, the data line 6a, and the capacitor line 7a have light shielding property. Accordingly, the region where the scanning line 3a, the data line 6a, the capacitance line 7a, and a conductive film of the same layer as these wirings are formed, is a light shielding region which light does not pass through, the region surrounded by the light shielding region is an aperture region which light passes through.

As illustrated in FIG. 6, FIG. 7 and FIG. 8, in the first substrate 19, on the surface 19s side of the first substrate 19, the interlayer insulating layers 40 to 49 are sequentially formed, and the surfaces of the interlayer insulating layers 41 and 43 to 49 are continuous planes by chemical mechanical polishing (CMP) or the like.

A third light shielding layer 1a is formed between the first substrate 19 and the interlayer insulating layer 40, and a fourth light shielding layer 2a is formed between an interlayer insulating layer 40 and an interlayer insulating layer 41. A transistor 30 including a semiconductor layer 31a, a gate insulating layer 32, and a gate electrode 33a is formed between the interlayer insulating layer 41 and the interlayer insulating layer 42. A first light shielding layer 4a is formed between the interlayer insulating layer 42 and the interlayer insulating layer 43. Between the interlayer insulating layer 43 and the interlayer insulating layer 44, a second light shielding layer 5a and relay electrodes 5d, 5s are formed. Between the interlayer insulating layer 44 and the interlayer insulating layer 45, the scanning line 3a and the relay electrodes 3d, 3s are formed. Between the interlayer insulating layer 45 and the interlayer insulating layer 46, the relay electrode 8a and the relay electrodes 8d, 8e, 8s are formed. Between the interlayer insulating layer 46 and the interlayer insulating layer 47, a holding capacity 55 is formed, and the first capacitor electrode 551, the first dielectric layer 556, the second capacitor electrode 552, the second dielectric layer 557, and the third capacitor electrode 553 are sequentially stacked. Between the interlayer insulating layer 47 and the interlayer insulating layer 48, the data line 6a and the relay electrodes 6b, 6c, 6d are formed. Between the interlayer insulating layer 48 and the interlayer insulating layer 49, the capacitance line 7a and the relay electrode 7d are formed. On the surface of the interlayer insulating layer 49 on the opposite side of the first substrate 19, the pixel electrode 9a and the first alignment film 18 are sequentially formed. In the present embodiment, the interlayer insulating layer 42, 43, 44 corresponds to the “first insulating layer” of the present disclosure, and the interlayer insulating layer 43 corresponds to the “second insulating layer” of the present disclosure, and the interlayer insulating layer 41 corresponds to the “third insulating layer” of the present disclosure.

Detailed Description of Each Layer

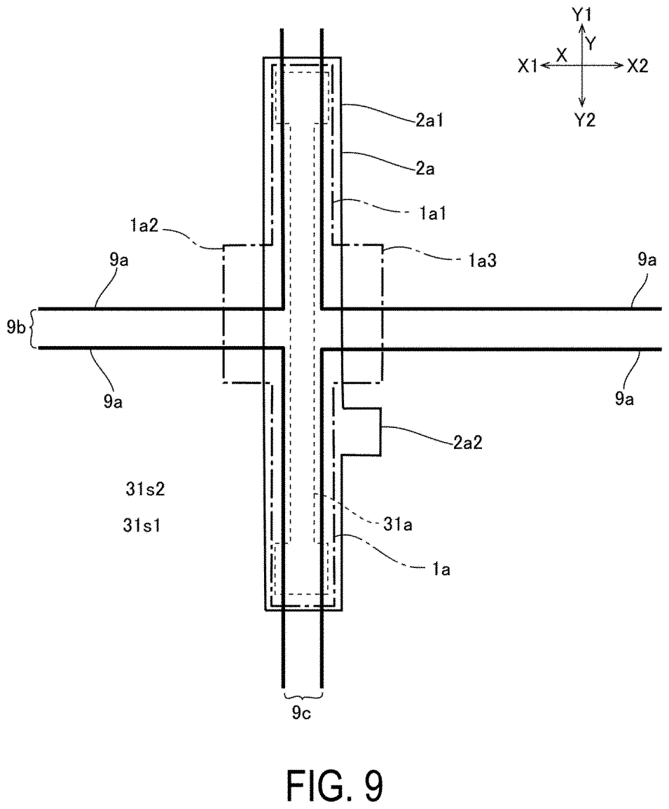

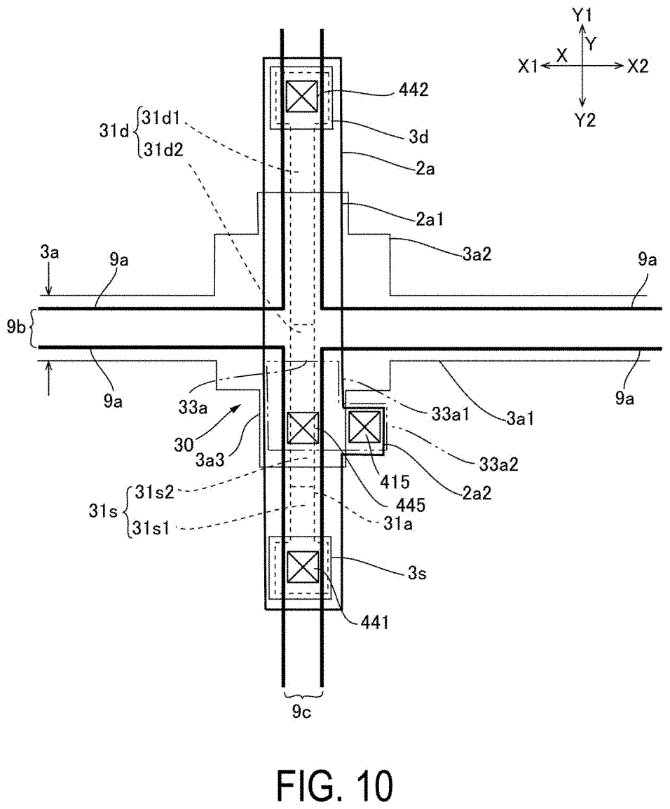

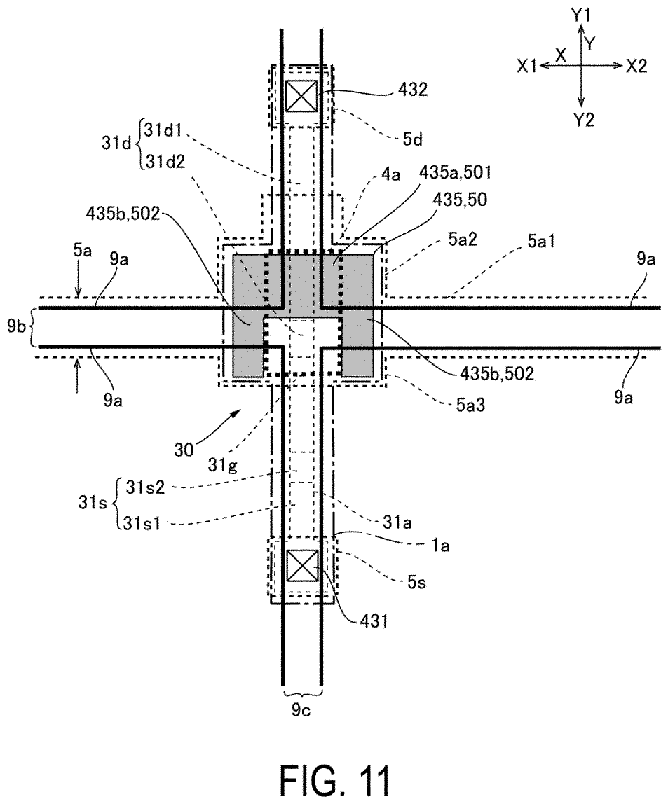

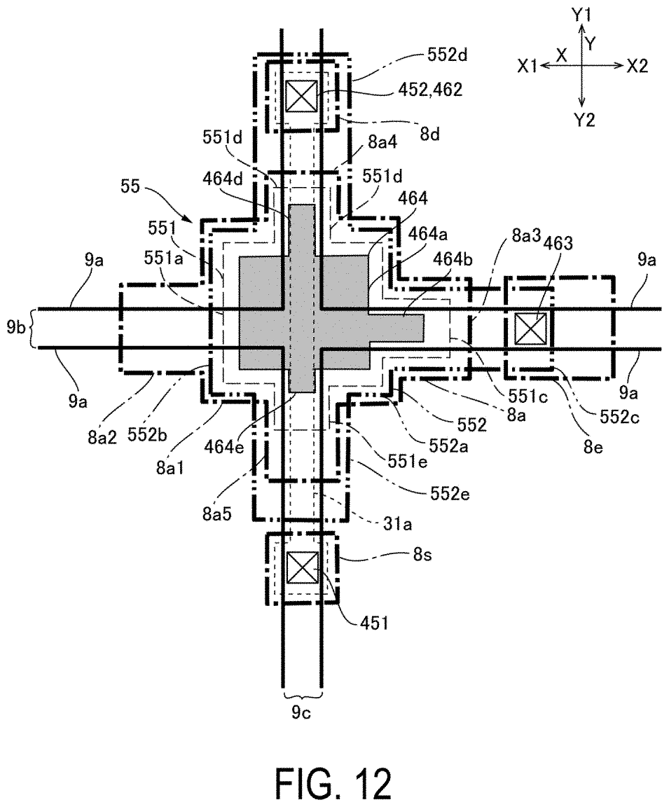

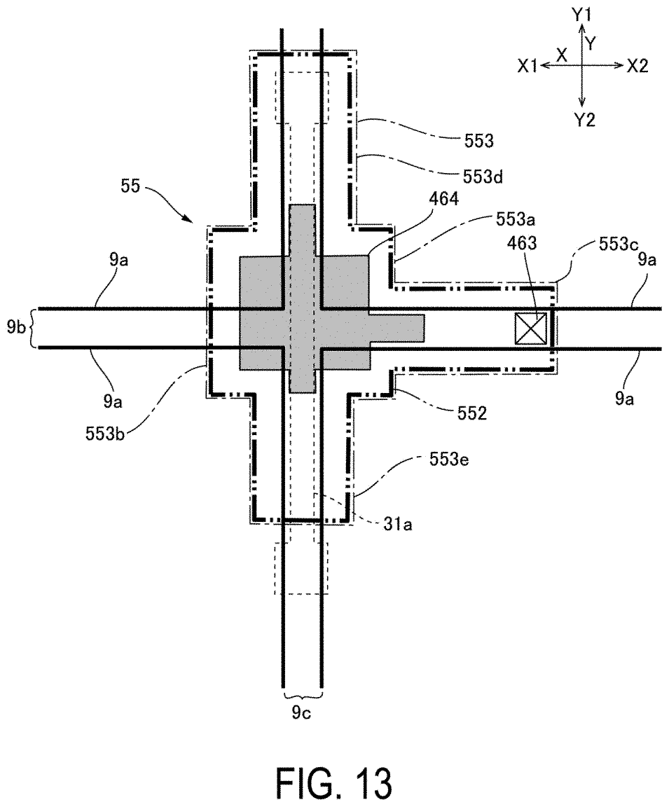

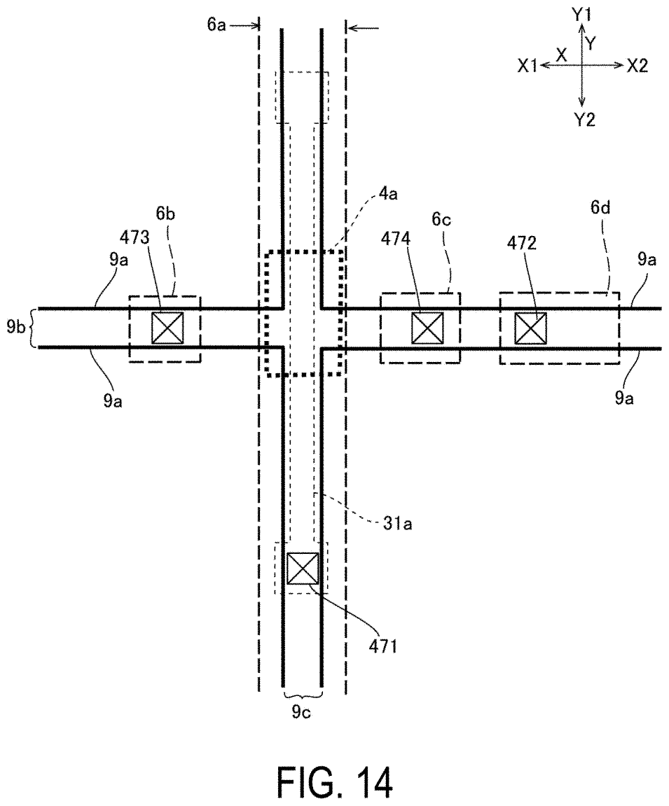

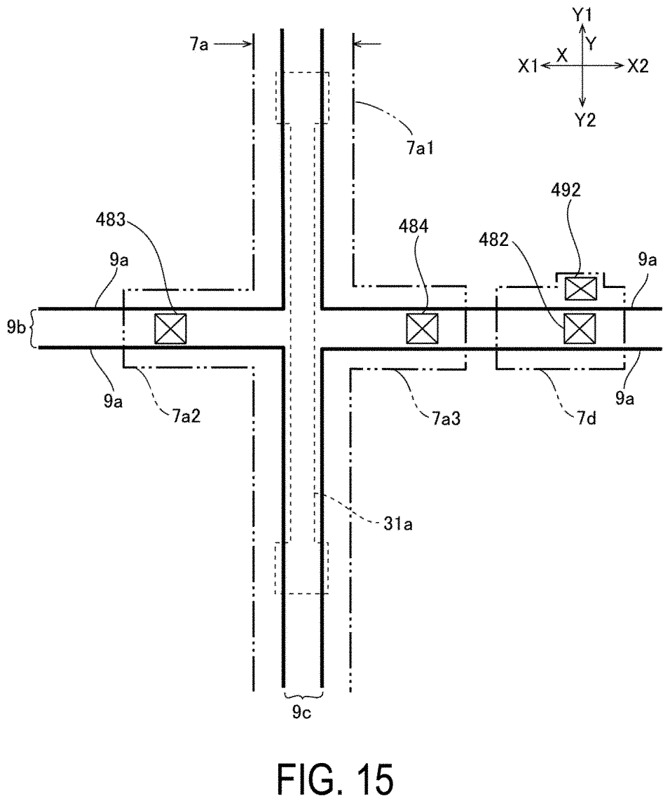

With reference to FIG. 6, FIG. 7 and FIG. 8, and with reference to FIG. 9 to FIG. 15 as appropriate, a detailed configuration of the first substrate 19 will be described. FIG. 9 is a plan view of a semiconductor layer 31a, a third light shielding layer 1a, the fourth light shielding layer 2a, and the like illustrated in FIG. 5. FIG. 10 is a plan view of the fourth light shielding layer 2a, a gate electrode 33a, a scanning line 3a, and the like illustrated in FIG. 5. FIG. 11 is a plan view of the third light shielding layer 1a, a first light shielding layer 4a, a second light shielding layer 5a, and the like illustrated in FIG. 5. FIG. 12 is a plan view of a first capacitor electrode 551, a second capacitor electrode 552, and the like illustrated in FIG. 5. FIG. 13 is a plan view of the second capacitor electrode 552, a third capacitor electrode 553, and the like illustrated in FIG. 5. FIG. 14 is a plan view of a data line 6a and the like illustrated in FIG. 5. FIG. 15 is a plan view of a capacitance line 7a and the like illustrated in FIG. 5. Note that FIG. 9 to FIG. 15 illustrate the contact holes related to the electrical connection of the electrodes and the like illustrated in those drawings, and illustrate the semiconductor layer 31a and the pixel electrode 9a for indicating the position to be referenced.

First, as illustrated in FIG. 6, FIG. 7, FIG. 8, and FIG. 9, in the first substrate 19, the semiconductor layer 31a extends in the Y-axis direction so as to overlap with the second inter-pixel region 9c in a planar manner, and on the lower layer side (first substrate 19 side) of the semiconductor layer 31a, between the first substrate 19 and the interlayer insulating layer 40, a third light shielding layer 1a overlapping with the semiconductor layer 31a in a planar manner is formed. The third light shielding layer 1a includes a body part 1a1 that extends in the Y-axis direction so as to overlap the semiconductor layer 31a in a planar manner with, a protruding portion 1a2 protruding from a substantially intermediate part in the length direction of the body part 1a1 to one side X1 in the X-axis direction, and a protruding portion 1a3 protruding from a substantially intermediate part in the length direction of the body part 1a1 to the other side in the X-axis direction.

On the lower layer side (first substrate 19 side) of the semiconductor layer 31a, between the interlayer insulating layer 40 and the interlayer insulating layer 41, a fourth light shielding layer 2a overlapping with the semiconductor layer 31a in a planar manner is formed. The fourth light shielding layer 2a includes a body part 2a1 that extends in the Y-axis direction so as to overlap with the semiconductor layer 31a in a planar manner, and a protruding portion 2a2 protruding to the other side X2 in the X-axis direction on a portion of the body part 2a1 in the length direction. The third light shielding layer 1a and the fourth light shielding layer 2a are formed of a light conductive film which has light shielding property, such as a conductive polysilicon film, a metal silicide film, a metal film, or a metal compound film. In the present embodiment, the third light shielding layer 1a and the fourth light shielding layer 2a are formed of a light shielding film such as a tungsten silicide (WSi), and a titanium nitride film.

As illustrated in FIG. 6, FIG. 7, FIG. 8 and FIG. 10, between the interlayer insulating layer 41 and the interlayer insulating layer 42, the transistor 30 includes a semiconductor layer 31a formed on a surface of the opposite side of the interlayer insulating layer 41 from the first substrate 19, a gate insulating layer 32 stacked on the opposite side of the semiconductor layer 31a from the first substrate 19, and a gate electrode 33a overlapping the middle part of the semiconductor layer 31a in the extending direction in a planar manner on the opposite side of the gate insulating layer 32 from the first substrate 19. The gate electrode 33a includes a body part 33a1 overlapping with a portion of the semiconductor layer 31a in a planar manner, and a protruding portion 33a2 projecting from the body part 33a1 to the other side X2 in the X-axis direction, and the protruding portion 33a2 overlaps with the protruding portion 2a2 of the fourth light shielding layer 2a in a planar manner.

The protruding portion 33a2 of the gate electrode 33a and the protruding portion 2a2 of the fourth light shielding layer 2a are electrically coupled through contact holes 415 that pass through the gate insulating layer 32 and the interlayer insulating layer 41, and the fourth light shielding layer 2a functions as a back gate.

The semiconductor layer 31a includes a channel region 31g overlapping with the gate electrode 33a in a planar manner, a first region 31d adjacent to the channel region 31g on one side Y1 in the Y-axis direction, and a second region 31s adjacent to the channel region 31g on the other side Y2 in the Y-axis direction. In the present embodiment, the transistor 30 has a lightly-doped drain (LDD) structure. Accordingly, the first region 31d includes a high concentration impurity region 31d1 into which high concentration impurities are introduced at a position separated from the channel region 31g, and a low concentration impurity region 31d2 having a lower impurity concentration than the high concentration impurity region 31d1 between the channel region 31g and the high concentration impurity region 31d1, and as described below, the high concentration impurity region 31d1 is electrically coupled to the pixel electrode 9a. Therefore, the low concentration impurity region 31d2 corresponds to the low concentration impurity region on the pixel electrode side. The second region 31s includes a high concentration impurity region 31s1 into which high concentration impurities are introduced at a position separated from the channel region 31g, and a low concentration impurity region 31s2 having a lower impurity concentration than the high concentration impurity region 31s1 between the channel region 31g and the high concentration impurity region 31s1, and as described below, the high concentration impurity region 31s1 is electrically coupled to the data line 6a.

The semiconductor layer 31a is formed of a polysilicon film (polycrystalline silicon film) or the like, and the gate insulating layer 32 includes a two-layer structure of a first gate insulating layer formed of a silicon oxide film formed by thermal oxidization of the semiconductor layer 31a, and a second gate insulating layer formed of a silicon oxide film formed by a low-pressure CVD method or the like. The gate electrode 33a is formed of a conductive film which has light shielding property, such as a conductive polysilicon film, a metal silicide film, a metal film, and a metal compound film.

Between the interlayer insulating layer 44 and the interlayer insulating layer 45, a scanning line 3a that extends in the X-axis direction so as to overlap with the first inter-pixel region 9b, a relay electrode 3d overlapping with the end of the first region 31d of the semiconductor layer 31a in a planar manner, and a relay electrode 3s overlapping in a planar manner with the end portion of the second region 31s of the semiconductor layer 31a are formed by the same conductive material. The scanning line 3a is formed of a conductive film which has light shielding property, such as a conductive polysilicon film, a metal silicide film, a metal film, or a metal compound film. The scanning line 3a includes a body part 3a1 that extends in the X-axis direction so as to intersect with the semiconductor layer 31a, a protruding portion 3a2 projecting from the body part 3a1 to the one side Y1 in the Y-axis direction so as to overlap with the semiconductor layer 31a from the body part 3a1 in a planar manner, and a protruding portion 3a3 projecting from the body part 3a1 to the other side Y2 in the Y-axis direction so as to overlap with the semiconductor layer 31a from the body part 3a1 in a planar manner, the protruding portion 3a3 overlaps the body part 33a1 of the gate electrode 33a in a planar manner. The protruding portion 3a3 of the scanning line 3a is electrically coupled to the gate electrode 33a through a first contact hole 445 that passes through the first insulating layer (interlayer insulating layer 42, 43, 44). Relay electrode 3d is electrically coupled to relay electrode 5d, which will be described later, through a contact hole 442 that passes through the interlayer insulating layer 44, and relay electrode 5s is electrically coupled to relay electrode 5s, which will be described later, through a contact hole 441 that passes through interlayer insulating layer 44.

As illustrated in FIG. 6, FIG. 7, FIG. 8, and FIG. 11, a conductive first light shielding layer 4a is formed between the interlayer insulating layer 42 and the interlayer insulating layer 43 (the layer between the gate electrode 33a and the scanning line 3a), so as to overlap with at least the low concentration impurity region 31d2 of the semiconductor layer 31a in a planar manner. The first light shielding layer 4a is formed of a conductive film which has light shielding property such as a conductive polysilicon film, a metal silicide film, a metal film, and a metal compound film.

Between the interlayer insulating layer 43 and the interlayer insulating layer 44, a second light shielding layer 5a overlapping in a plan view with the first light shielding layer 4a, a relay electrode 5d overlapping in a planar manner at the end portion of the first region 31d of the semiconductor layer 31a, and a relay electrode 5s overlapping in a planar manner with the end portion of the second region 31s of the semiconductor layer 31a are formed by the same conductive material. The second light shielding layer 5a is formed of a conductive film which has light shielding property such as a conductive polysilicon film, a metal silicide film, a metal film, and a metal compound film.

The relay electrode 5d is electrically coupled to the high concentration impurity region 31d1 of the semiconductor layer 31a through a contact hole 432 that passes through the interlayer insulating layer 42, 43 and the gate insulating layer 32, and the relay electrode 5s is electrically coupled to the high concentration impurity region 31s1 of the semiconductor layer 31a through a contact hole 431 that passes through the interlayer insulating layer 42, 43 and the gate insulating layer 32.

The second light shielding layer 5a includes a body part 5a1 that extends in the X-axis direction so as to overlap with the first inter-pixel region 9b in a planar manner, a protruding portion 5a2 projecting from the body part 5a1 to one side Y1 in the Y-axis direction so as to overlap with the semiconductor layer 31 a from the body part 5a1 in a planar manner, and a protruding portion 5a3 projecting from the body part 5a1 to the other side Y2 in the Y-axis direction so as to overlap with the semiconductor layer 31 a in a planar manner, and the second light shielding layer 5a overlaps the first light shielding layer 4a in a planar manner.

The second light shielding layer 5a is a constant potential line to which a constant potential is applied, and electrically couples to the first light shielding layer 4a via a light shielding portion 50, which will be described later. Therefore, a constant potential is applied to the first light shielding layer 4a via the second light shielding layer 5a. In the present embodiment, a common potential Vcom is applied to the second light shielding layer 5a as a constant potential, and thus the common potential Vcom is applied to the first light shielding layer 4a as a constant potential.

On a side of the semiconductor layer 31a than the second light shielding layer 5a, a light shielding portion 50 electrically coupled with the first light shielding layer 4a is formed, and the light shielding portion 50 covers a part of the semiconductor layer 31a in a planar manner. More specifically, the light shielding portion 50 includes a first portion 501 that overlaps the first light shielding layer 4a and a pair of second portions 502 protruding from the first portion 501 to the semiconductor layer 31a side, and the first light shielding layer 4a overlaps with the low concentration impurity region 31d2 in a planar manner, and the second portion 502 of the light shielding portion 50 is disposed along the low concentration impurity region 31d2 on both sides in the width direction of the low concentration impurity region 31d2.

More specifically, between the first light shielding layer 4a and the second light shielding layer 5a, a second contact hole 435 that passes through the second insulating layer (interlayer insulating layer 43) which covers the first light shielding layer 4a is formed, and in the second contact holes 435, a first portion 501 of the light shielding portion 50 is positioned inside the first hole portion 435a that overlaps with the first light shielding layer 4a in a planar manner. Accordingly, the first portion 501 electrically couples the first light shielding layer 4a and the second light shielding layer 5a in a state overlapping with the first light shielding layer 4a from the opposite side of the transistor 30.

The second contact hole 435 includes a pair of second hole portions 435b protruding from the first hole portion 435a toward both sides in the width direction of the semiconductor layer 31a on the side of the end portion of the first light shielding layer 4a, and the second portion 502 of the light shielding portion 50 is positioned inside each of the pair of second hole portions 435b. Therefore, the second portion 502 protrudes toward both sides in the width direction of the semiconductor layer 31a on the side of the end portion of the first light shielding layer 4a, and covers the low concentration impurity region 31d2 from both sides in the width direction. In the present embodiment, the second portion 502 is in contact with the side surface of the first light shielding layer 4a.

In the second contact hole 435, the pair of second hole portions 435b reaches the third light shielding layer 1a on both sides in the width direction of the low concentration impurity region 31d2. Accordingly, the second portion 502 electrically couples to the third light shielding layer 1a on both sides in the width direction of the low concentration impurity region 31d2, and electrically couples the third light shielding layer 1a and the first light shielding layer 4a. Therefore, a constant potential is applied to the third light shielding layer 1a.

In the present embodiment, the first hole portion 435a of the second contact hole 435 overlaps in a planar manner at the end portion of the first light shielding layer 4a on the opposite side of the channel region 31g, and the second hole portion 435b extends in a planar manner from the first hole portion 435a toward the side of the channel region 31g along both side surfaces in the channel width direction (X-axis direction) of the first light shielding layer 4a. Accordingly, the first portion 501 of the light shielding portion 50 overlaps in a planar manner at the end portion of the first light shielding layer 4a on the opposite side of the channel region 31g, and the second portion 502 extends in a planar manner from the first portion 501 toward the side of the channel region 31g along both side surfaces in the channel width direction (X-axis direction) of the first light shielding layer 4a.

To achieve such a configuration, in the present embodiment, after the second contact hole 435 is formed, the second contact hole 435 is filled with a metal such as tungsten, after that, the surface of the interlayer insulating layer 43 is formed as a continuous plane by chemical mechanical polishing or the like. As a result, the light shielding portion 50 is formed as a plug, and the surface of the light shielding portion 50 (plug) configures a plane that is continuous with the surface of the interlayer insulating layer 43. Note that, there may be an aspect that the first portion 501 of the light shielding portion 50 overlaps the end portion of the first light shielding layer 4a on the channel region 31g side, and the second portion 502 extends in a planar manner toward the first region 31d along both side surfaces in the channel width direction (X-axis direction) of the first light shielding layer 4a. Further, there may be an aspect that the first portion 501 of the light shielding portion 50 overlaps the entire surface of the first light shielding layer 4a in a planar manner.

As illustrated in FIG. 6, FIG. 7, FIG. 8, and FIG. 12, between the interlayer insulating layer 45 and the interlayer insulating layer 46, the relay electrode 8a overlapping in a planar manner with the first light shielding layer 4a and the second light shielding layer 5a, and the relay electrode 8d overlapping in a planar manner at the end of the first region 31d of the semiconductor layer 31a, and the relay electrode 8s overlapping in a planar manner at the end of second region 31s of semiconductor layer 31a, and the relay electrode 8e separated from the relay electrode 8a on the other side X2 in the X-axis direction, are formed of the same conductive material. The relay electrode 8a is formed of a conductive film which has light shielding property, such as a conductive polysilicon film, a metal silicide film, a metal film, and a metal compound film. The relay electrode 8d is electrically coupled to relay electrode 3d through contact hole 452 that passes through the interlayer insulating layer 45, and the relay electrode 8s is electrically coupled to relay electrode 3s through contact hole 451 that passes through the interlayer insulating layer 45.

A through hole 464 that exposes the relay electrode 8a at the bottom is formed in the interlayer insulating layer 46. On the inside of the through hole 464 and on the surface of the interlayer insulating layer 46 outside the through hole 464A on the opposite side of the transistor 30, first capacitor electrode 551 of a holding capacitor 55 is formed, and the first capacitor electrode 551 is electrically coupled to the relay electrode 8a at the bottom of the through hole 464. In addition, on the opposite side of the transistor 30 with respect to the first capacitor electrode 551, a first dielectric layer 556 and a second capacitor electrode 552 are sequentially stacked. The first capacitor electrode 551 and the second capacitor electrode 552 are formed of conductive films which have light shielding property, such as a conductive polysilicon film, a metal silicide film, a metal film, a metal compound film, and the like.

The relay electrode 8a has, in a planar manner, a quadrangular body part 8a1 that overlaps with the transistor 30, protruding portions 8a2, 8a3 projecting from the body part 8a1 on both sides in the X-axis direction, and protruding portions 8a4, 8a5 protruding from the body part 8a1 on both sides in the Y-axis direction. The first capacitor electrode 551 includes a quadrangular body part 551a that overlaps the body part 8a1 of the relay electrode 8a, a protruding part 551c protruding from the body part 551a to the other side X2 in the X-axis direction, and protruding parts 551d, 551e protruding from the body part 8a1 on both sides in the Y-axis direction.

The second capacitor electrode 552 includes a body part 552a that overlaps with the body part 551a of the first capacitor electrode 551, and protruding portions 552b, 552c protruding from the body part 552a on both sides in the X-axis direction, and the protruding portion 551d, 551e protruding from the body part 552a on both sides in the Y-axis direction, and the protruding portion 552c is electrically coupled to the relay electrode 8e through a contact hole 463 that passes through the interlayer insulating layer 46. The protruding portion 552d is electrically coupled to the relay electrode 8d through a contact hole 462 that passes through the interlayer insulating layer 46. In accordance with such a planar shape, the through hole 464 includes a body part 464a that overlaps with the body part 551a of the first capacitor electrode 551, a protruding portion 464b protruding from the body part 464a to the other side X2 in the X-axis direction, and protruding portions 464d, 464e protruding from the body part 464a on both sides in the Y-axis direction.

As illustrated in FIG. 6, FIG. 7, FIG. 8, and FIG. 13, on the opposite side of the transistor 30 with respect to the second capacitor electrode 552, a second dielectric layer 557 and a third capacitor electrode 553 are sequentially stacked. The third capacitor electrode 553 includes a body part 553a that overlaps with the body part 552a of the second capacitor electrode 552, protruding portions 553b, 553c projecting from the body part 553a on both sides in the X-axis direction, and protruding portions 553d, 553e protruding from the body part 553a on both sides in the Y-axis direction. The third capacitance electrode 553 is formed of a conductive film which has light shielding property such as a conductive polysilicon film, a metal silicide film, a metal film, and a metal compound film.

Here, the first capacitor electrode 551, the first dielectric layer 556, the second capacitor electrode 552, the second dielectric layer 557, and the third capacitor electrode 553 overlap the entire bottom and side walls of the through hole 464.

As illustrated in FIG. 6, FIG. 7, FIG. 8, and FIG. 14, between the interlayer insulating layer 47 and the interlayer insulating layer 48, a data line 6a extending in the Y-axis direction so as to overlap with the second inter-pixel region 9c, the relay electrode 6b that is separated from the data line 6a on one side X1 in the X-axis direction, and relay electrodes 6c, 6d that are separated from the data line 6a on the other side X2 in the X-axis direction are formed by the same conductive material. The data line 6a is formed of a conductive film which has light shielding property such as a conductive polysilicon film, a metal silicide film, a metal film, and a metal compound film.

The data line 6a is electrically coupled to the relay electrode 8s through a contact hole 471 that passes through the interlayer insulating layers 46, 47. Accordingly, the data line 6a electrically couples to the high concentration impurity region 31s1 of the semiconductor layer 31a via the relay electrodes 8s, 3s and 5s, and applies an image signal to the second region 31s.

The relay electrode 6b is electrically coupled to the relay electrode 8a through a contact hole 473 that passes through the interlayer insulating layer 47. The relay electrode 6c is electrically coupled to the third capacitor electrode 553 through a contact hole 474 that passes through the interlayer insulating layer 47. The relay electrode 6d is electrically coupled to the relay electrode 8e through a contact hole 472 that passes through the interlayer insulating layers 46 and 47.

As illustrated in FIG. 6, FIG. 7, FIG. 8, and FIG. 15, between the interlayer insulating layer 48 and the interlayer insulating layer 49, a capacitance line 7a extending in the Y-axis direction so as to overlap with the second inter-pixel region 9c, and the relay electrode 7d, which is separated from the capacitor line 7a on the other side X2 in the X-axis direction, are formed of the same conductive material. The capacitance line 7a includes a conductive film which has light shielding property, such as a conductive polysilicon film, a metal silicide film, a metal film, or a metal compound film.

The capacitor line 7a includes a body part 7a1 that extends along the second inter-pixel region 9c, a protruding portion 7a2 protruding from the body part 7a1 to the one side X1 in the X-axis direction, and a protruding portion 7a3 protruding from the body part 7a1 to the other side X2 in the X-axis direction. The protruding portion 7a2 is electrically coupled to the relay electrode 6b through a contact hole 483 that passes through the interlayer insulating layer 48. Accordingly, capacitor line 7a is electrically coupled to relay electrode 8a via relay electrode 6b, and a common potential Vcom is applied to relay electrode 8a. The protruding portion 7a3 is electrically coupled to the relay electrode 6c through a contact hole 484 that passes through the interlayer insulating layer 48. Accordingly, the capacitor line 7a electrically couples to the third capacitor electrode 553 via the relay electrode 6c, and applies a common potential Vcom to the third capacitor electrode 553. On the other side, the relay electrode 7d is electrically coupled to the relay electrode 6d through a contact hole 482 that passes through the interlayer insulating layer 48.

A pixel electrode 9a is formed on the surface of the interlayer insulating layer 49 on the opposite side of the transistor 30, and the pixel electrode 9a is electrically coupled to the relay electrode 7d through a contact hole 492 that passes through the interlayer insulating layer 49. Accordingly, the pixel electrode 9a is electrically coupled to the second capacitor electrode 552 via the relay electrodes 7d, 6d, 8e and 8a, and the pixel electrode 9a is further electrically coupled to the high concentration impurity region 31d1 of the semiconductor layer 31a via the second capacitor electrode 552 and the relay electrodes 8d, 3d and 5d. Accordingly, when the transistor 30 is on, the image signal supplied from the data line 6a is electrically coupled to the second capacitor electrode 552 and the pixel electrode 9a of the holding capacitor 55.

In the holding capacity 55, the first capacitor electrode 551 faces the second capacitor electrode 552 via the first dielectric layer 556, and the third capacitor electrode 553 faces the second capacitor electrode 552 via the second dielectric layer 557. Here, while the common potential Vcom is applied to the first capacitor electrode 551 and the third capacitor electrode 553, on the other hand, the second capacitor electrode 552 is electrically coupled to the pixel electrode 9a. Accordingly, the holding capacity 55 is configured so that the capacitive element between the second capacitor electrode 552 and the first capacitor electrode 551, and the capacitive element between the second capacitor electrode 552 and the third capacitor electrode 553 are electrically coupled in parallel. In addition, the first capacitor electrode 551, the first dielectric layer 556, the second capacitor electrode 552, the second dielectric layer 557, and the third capacitor electrode 553 overlap at the bottom and the entire side wall of the through hole 464, and an opposing area is wide. As a result, the electrostatic capacitance of the holding capacity 55 is large.

### Main Effects of the Present Embodiment

As described above, in the electro-optical device 100 according to the present embodiment, the scanning line 3a is electrically coupled to the gate electrode 33a through the first contact hole 445 of the first insulating layer (interlayer insulating layers 42, 43, 44) which covers the transistor 30, and a first light shielding layer 4a to which a constant potential (Vcom) is applied is disposed in a layer between the gate electrode 33a and the scanning line 3a (between the interlayer insulating layer 42 and the interlayer insulating layer 43). In addition, the light shielding portion 50 electrically coupled to the first light shielding layer 4a covers the part of the semiconductor layer 31a (low concentration impurity region 31d2). Thus, even when light incident from the side of the pixel electrode 9a or the diffraction light thereof travels toward the low concentration impurity region 31d2 of the semiconductor layer 31a, such light is shielded by the first light shielding layer 4a and the light shielding portion 50, therefore, operation defects and the like due to photocurrent are less likely to occur in the transistor 30. In addition, the first light shielding layer 4a and the light shielding portion 50 are applied with a constant potential (Vcom) on the side of the semiconductor layer 31a than the scanning line 3a, the effect of the potential of the scanning line 3a is less likely to reach the transistor 30.

In addition, the first light shielding layer 4a is disposed so as to overlap in a planar manner with a part of the semiconductor layer 31a (the low concentration impurity region 31d2), and the light shielding portion 50 is provided in a region of the interlayer insulating layers 43, 44 that overlap with the first light shielding layer 4a in a planar manner, and the second contact hole 435 formed in a region protruding from the first light shielding layer 4a. Thus, the second contact hole 435 includes a first hole portion 435a positioned between the first light shielding layer 4a and the second light shielding layer 5a, and a second hole portion 435b protruding from the first hole portion 435a to the semiconductor layer 31a side, the light shielding portion 50 includes a first portion 501 that overlaps with the first light shielding layer 4a, and a second portion 502 that protrudes toward the semiconductor layer 31a from the first portion 501. Therefore, the low concentration impurity regions 31d2 of the semiconductor layer 31a can be covered over a wide range by the first light shielding layer 4a and the light shielding portion 50. Thus, even when light incident from the side of the pixel electrode 9a or the diffracted light thereof travels toward the semiconductor layer 31a, the light is shielded by the first light shielding layer 4a and the light shielding portion 50, therefore, operation defects and the like due to photocurrent are less likely to occur in the transistor 30.

Furthermore, when forming the second contact hole 435, the first light shielding layer 4a functions as an etching stopper, so the semiconductor layer 31a is less likely to be damaged by etching. Thus, in the vicinity of the low concentration impurity region 31d2, the second hole 435b of the second contact hole 435 and the second portion 502 of the light shielding portion 50 can be disposed. Further, a constant potential can be supplied to the first light shielding layer 4a from the opposite side of the transistor 30. In addition, a constant potential supplying with respect to the first light shielding layer 4a and a light shielding with respect to the semiconductor layer 31a can be performed by the light shielding portion 50.

In addition, the second portion 502 is coupled to the third light shielding layer 1a disposed on the opposite side of the first light shielding layer 4a with respect to the transistor 30, thus, even when light emitted from the first substrate 19 is incident to the semiconductor layer 31a as return light from the first substrate 19, such the light can be shielded by the third light shielding layer 1a.

In addition, a fourth light shielding layer 2a overlapping with the semiconductor layer 31a via a third insulating layer (interlayer insulating layer 41) on the opposite side of the gate electrode 33a is disposed, and the fourth light shielding layer 2a is electrically coupled to the gate electrode 33a. Thus, the fourth light shielding layer 2a functions as a back gate.

Furthermore, a retention capacitor 55 is formed in a region overlapping the first light shielding layer 4a from the opposite side of the transistor 30. Thus, even when light incident from the side of the pixel electrode 9a or the diffracted light thereof is to travel toward the semiconductor layer 31a, such light can be shielded by the retention capacitor 55.

### Embodiment 2

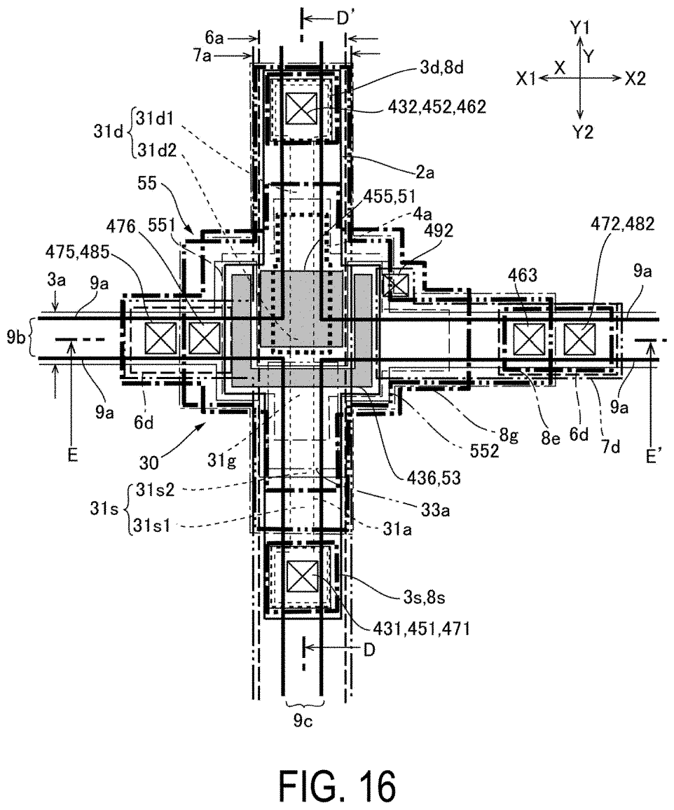

An embodiment 2 of the present disclosure will be described herein with reference to FIG. 16 to FIG. 25. Note that in the present embodiment, the third light shielding layer 1a, the second light shielding layer 5a, the interlayer insulating layer 40, 44, and the like described with reference to the embodiment 1 are not disposed, but the basic configuration is the same as that of the embodiment 1. Therefore, common components are referenced using like numbers, and no descriptions for such components are provided below.

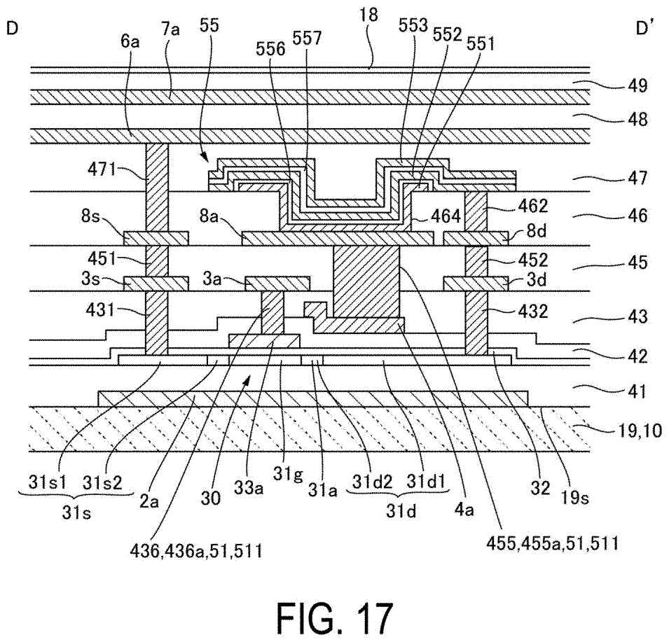

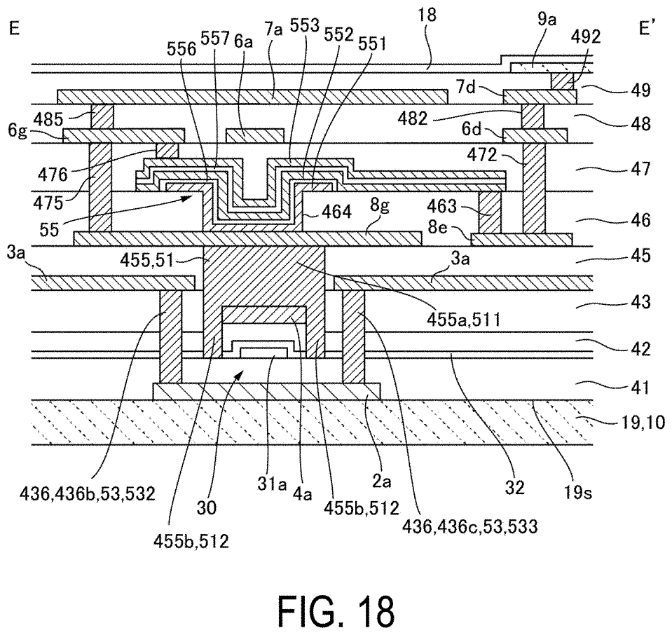

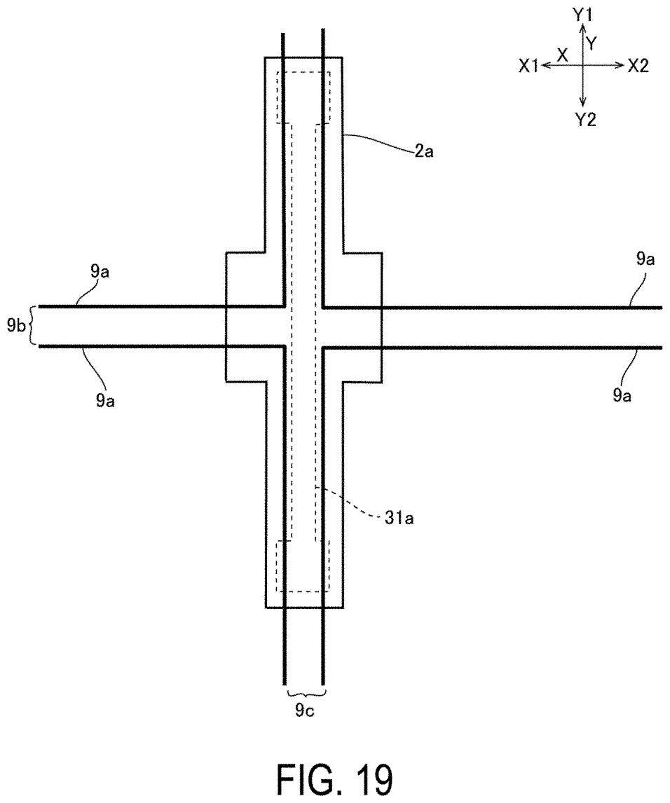

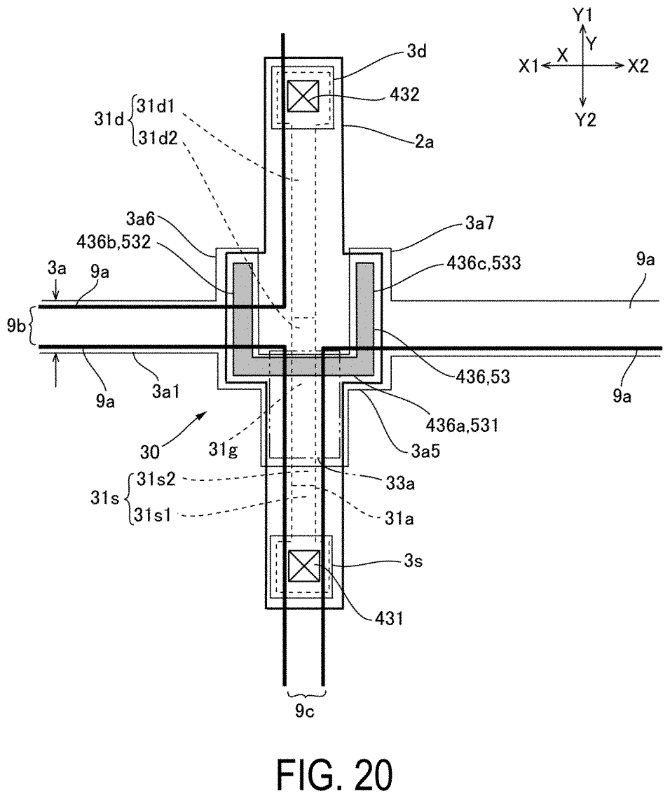

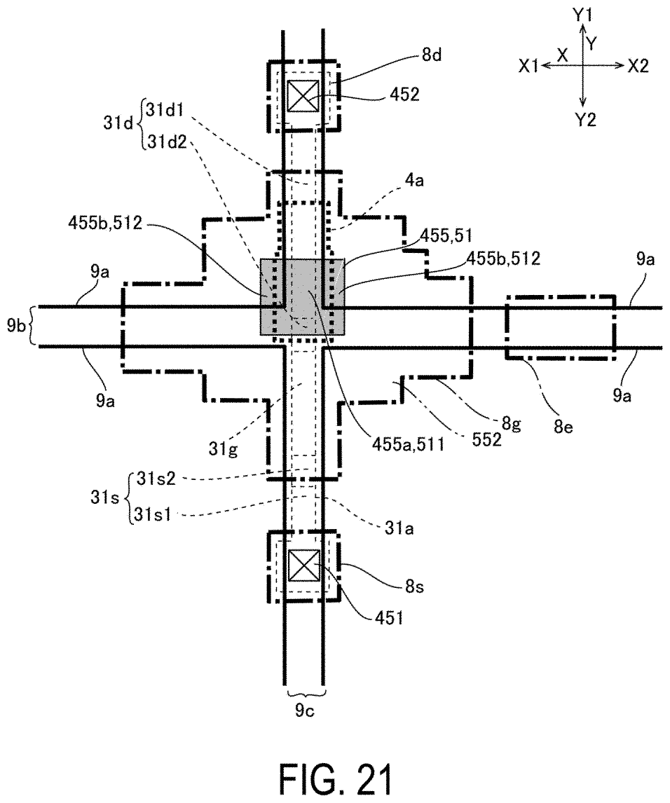

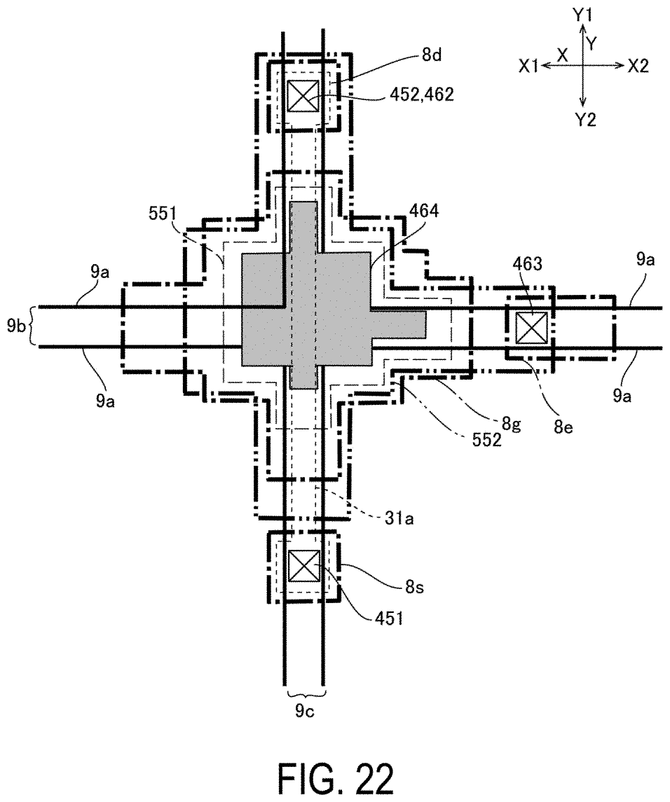

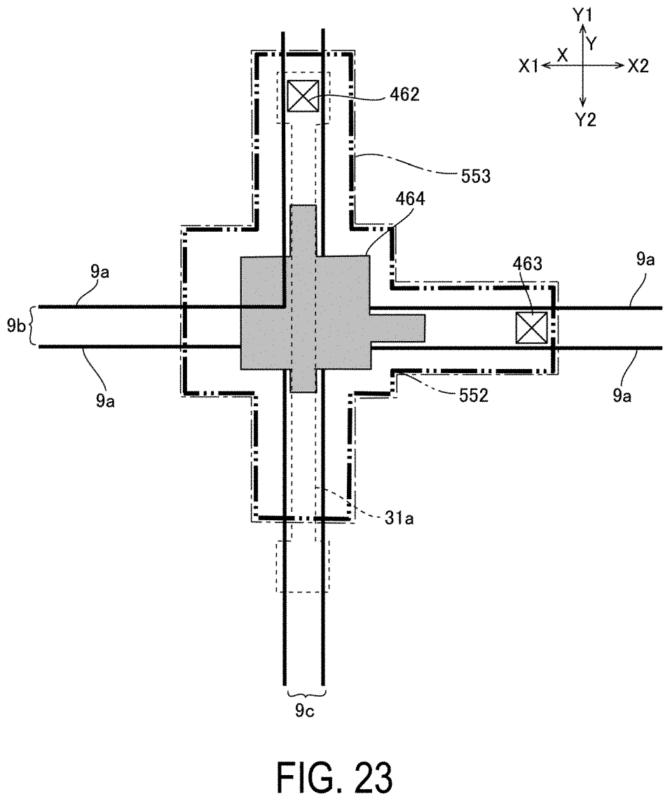

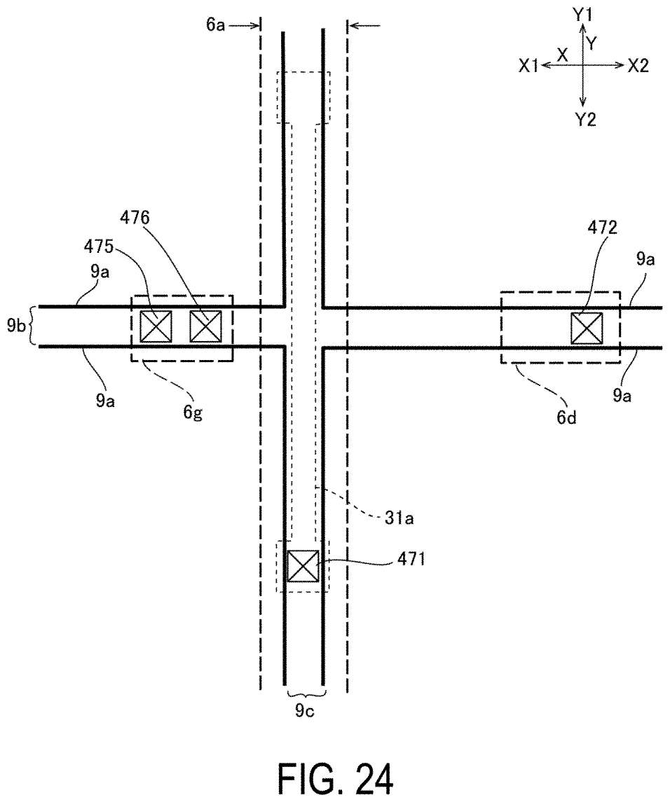

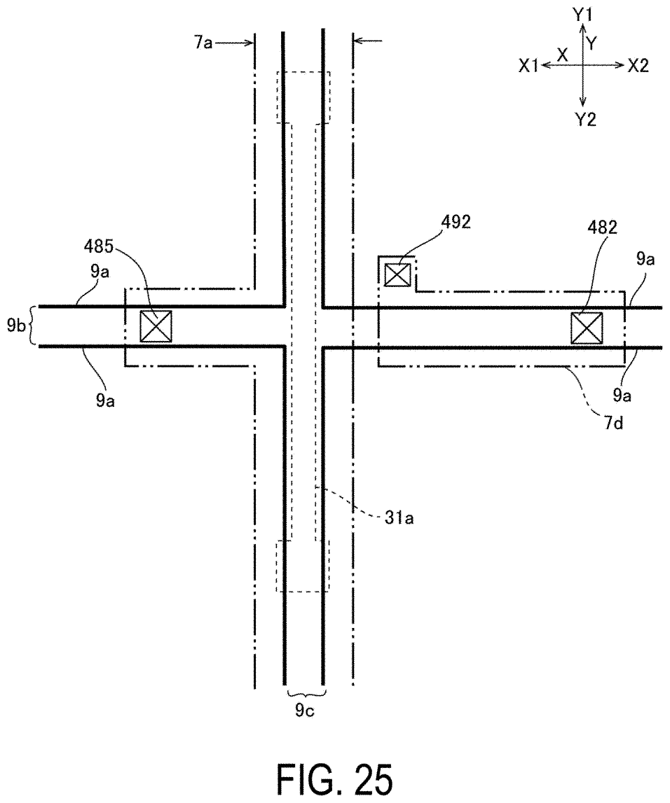

FIG. 16 is an explanatory diagram of an electro-optical device 100 according to embodiment 2 of the present disclosure, and illustrates the periphery of the transistor 30 in an enlarged manner. FIG. 17 is a D-D′ cross-sectional view of the transistor 30 illustrated in FIG. 16, and is a cross-sectional view schematically illustrating a case of cutting along the semiconductor layer 31a. FIG. 18 is an E-E′ cross-sectional view of the transistor 30 illustrated in FIG. 16, and is a cross-sectional view schematically illustrating a case of cutting along the scanning line 3a. FIG. 19 is a plan view of the semiconductor layer 31a, the fourth light shielding layer 2a, and the like illustrated in FIG. 16. FIG. 20 is a plan view of the fourth light shielding layer 2a, a gate electrode 33a, a scanning line 3a, and the like illustrated in FIG. 16. FIG. 21 is a plan view of the first light shielding layer 4a, the second light shielding layer 8a illustrated in FIG. 16. FIG. 22 is a plan view of the first capacitor electrode 551, the second capacitor electrode 552, and the like illustrated in FIG. 16. FIG. 23 is a plan view of the second capacitor electrode 552, the third capacitor electrodes 553, and the like illustrated in FIG. 16. FIG. 24 is a plan view of the data line 6a and the like illustrated in FIG. 16. FIG. 25 is a plan view of the capacitance line 7a and the like illustrated in FIG. 16. Note that, FIG. 18 also illustrates a contact hole 492 electrically coupling the pixel electrode 9a and a relay electrode 7a. Note that FIG. 19 to FIG. 25 illustrate the contact holes related to the electrically coupling of the electrodes and the like illustrated in those drawings, and illustrate the semiconductor layer 31a and the pixel electrode 9a for indicating the position to be referenced. Also note that in FIG. 16 and FIG. 19 to FIG. 25 described below, the layers are represented by the following lines. Further, in FIG. 16 and FIG. 19 to FIG. 25, for the layers in which the end portions overlap in a plan view with each other, the end portions are shifted to make the shape and the like of the layers easily recognizable.

Fourth light shielding layer 2a is represented by medium-thickness solid line.

Semiconductor layer 31a is represented by very thin short dashed line.

Gate electrode 33a is represented by very thin two-dot chain line.

First light shielding layer 4a is represented by very thick short dashed line.

Scanning line 3a is represented by very thin solid line.

Relay electrode 8a is represented by very thick dot-dash line.

First capacitor electrode 551 is represented by very thin long dashed line.

Second capacitance electrode 552 is represented by very thick two-dot chain line.

Third capacitance electrode 553 is represented by very thin dot chain line.

Data line 6a is represented by medium-thickness long dashed line.

Capacitance line 7a is represented by medium-thickness two-dot chain line.

Pixel electrode 9a is represented by very thick solid line.

As illustrated in FIG. 16, even in the present embodiment, the pixel electrode 9a is formed in each of the plurality of pixels 100a, and the scanning lines 3a, the data lines 6a, and the capacitor lines 7a extend along the inter-pixel regions sandwiched by the adjacent pixel electrodes 9a. The scanning line 3a, the data line 6a, the capacitance line 7a, and a region where a conductive film is formed in the same layer as the wiring is the light shielding region through which light does not transmit, and the region surrounded by the light shielding region serves as an aperture region through which light transmits.

As illustrated in FIG. 17 and FIG. 18, in the first substrate 19, the interlayer insulating layer 41-43, 45-49 is sequentially formed on one surface 19s side of the first substrate 19, and the surface of the interlayer insulating layer 43, 45-49 is formed in a continuous plane by chemical mechanical polishing or the like.

A fourth light shielding layer 2a is formed between the first substrate 19 and the interlayer insulating layer 41. A transistor 30 including a semiconductor layer 31a, a gate insulating layer 32, and a gate electrode 33a is formed between the interlayer insulating layer 41 and the interlayer insulating layer 42. A first light shielding layer 4a is formed between the interlayer insulating layer 42 and the interlayer insulating layer 43. Between the interlayer insulating layer 43 and the interlayer insulating layer 45, the scanning line 3a and the relay electrodes 3d, 3s are formed. Between the interlayer insulating layer 45 and the interlayer insulating layer 46, the relay electrode 8a and the relay electrodes 8d, 8e, 8s are formed. Between the interlayer insulating layer 46 and the interlayer insulating layer 47, a holding capacity 55 is formed, and the first capacitor electrode 551, the first dielectric layer 556, the second capacitor electrode 552, the second dielectric layer 557, and the third capacitor electrode 553 are sequentially stacked. Between the interlayer insulating layer 47 and the interlayer insulating layer 48, the data line 6a and relay electrodes 6d, 6g are formed. Between the interlayer insulating layer 48 and the interlayer insulating layer 49, the capacitance line 7a and the relay electrode 7d are formed. On the surface of the interlayer insulating layer 49 on the opposite side of the first substrate 19, the pixel electrode 9a and the first alignment film 18 are sequentially formed. In the present embodiment, the interlayer insulating layer 42, 43 corresponds to the “first insulating layer” in the present disclosure, and the interlayer insulating layer 43, 45 corresponds to the “second insulating layer” of the present disclosure.

First, as illustrated in FIG. 17, FIG. 18, and FIG. 19, in the first substrate 19, the semiconductor layer 31a extends in the Y-axis direction so as to overlap in a planar manner with the second inter-pixel region 9c, and on the lower layer side (first substrate 19 side) of the semiconductor layer 31a, a fourth light shielding layer 2a that overlaps with the semiconductor layer 31a in a planar manner is formed between the first substrate 19 and the interlayer insulating layer 41. The fourth conductive layer 2a is formed of a conductive film which has light shielding property such as a conductive polysilicon film, a metal silicide film, a metal film, and a metal compound film. In the present embodiment, the fourth light shielding layer 2a is formed of a light shielding film such as a tungsten silicide (WSi) film, and a titanium nitride film.

As illustrated in FIG. 17, FIG. 18 and FIG. 20, between the interlayer insulating layer 41 and the interlayer insulating layer 42, the transistor 30 includes a semiconductor layer 31a formed on a surface of the interlayer insulating layer 41 on the opposite side of the first substrate 19, the gate insulating layer 32 stacked on the semiconductor layer 31a on the opposite side of the first substrate 19, and a gate electrode 33a in a planar manner overlapping with a middle part of the semiconductor layer 31a in an extending direction of the gate insulating layer 32 on the opposite side of the first substrate 19. The semiconductor layer 31a includes a channel region 31g overlapping in a planar manner with the gate electrode 33a, a first region 31d adjacent to the channel region 31g on one side Y1 in the Y-axis direction, and a second region 31s adjacent to the channel region 31g on the other side Y2 in the Y-axis direction. In the present embodiment, the transistor 30 includes an LDD structure as in the embodiment 1. The gate electrode 33a is formed of a conductive film which has light shielding property, such as a conductive polysilicon film, a metal silicide film, a metal film, and a metal compound film. The relay electrode 3d is electrically coupled to the high concentration impurity region 31d1 through the contact hole 432 that passes through the interlayer insulating layer 43, and the relay electrode 3s is electrically coupled to the high concentration impurity region 31s1 through a contact hole 431 that passes through the interlayer insulating layer 43.

Between the interlayer insulating layer 43 and the interlayer insulating layer 45, a scanning line 3a that extends in the X-axis direction so as to overlap with the first inter-pixel region 9b, a relay electrode 3d overlapping in a planar manner at the end of the first region 31d of the semiconductor layer 31a, and a relay electrode 3s that overlaps with the end portion of the second region 31s of the semiconductor layer 31a are formed by the same conductive material. The scanning line 3a includes a conductive film which has light shielding property such as a conductive polysilicon film, a metal silicide film, a metal film, or a metal compound film.

The scanning line 3a includes a bent portion 3a5, in which a part of the body part 3a1 that extends in the X-axis direction so as to intersect with the semiconductor layer 31a overlaps with the semiconductor layer 31a, is bent toward the second region 31s in the Y-axis direction, and the protruding portions 3a6 and 3a7 that protrude on one side Y1 in the Y-axis direction on both sides in the channel width direction of the semiconductor layer 31a, and the bent portion 3a5 overlaps with a part of the gate electrode 33a in a planar manner. Here, the first contact hole 436 extending through the interlayer insulating layers 41, 42, 43 and the gate insulating layer 32 is formed in a part that overlaps with the bent portion 3a5 and the protruding portions 3a6 and 3a7 in a planar manner, and the scanning line 3a is electrically coupled to the gate electrode 33a and the fourth light shielding layer 2a through the first contact hole 436. Accordingly, the fourth light shielding layer 2a functions as a back gate. Note that the conductive material disposed inside the first contact hole 436 configures the light shielding wall 53.

The first contact hole 436 includes a first groove 436a that overlaps with the gate electrode 33a in a planar manner and second grooves 436b, 436c that extend so as to overlap with the protruding portions 3a6, 3a7 and that extend along the semiconductor layer 31a on both sides of the low concentration impurity region 31d2a of the semiconductor layer 31a. Accordingly, the light shielding wall 53 includes a first wall portion 531 that electrically couples the scanning line 3a and the gate electrode 33a within the first groove 436a, and second wall portions 532, 533 that electrically couple the scanning line 3a and the fourth light shielding layer 2a inside the second grooves 436b, 436c.

To achieve such a configuration, in the present embodiment, after the first contact hole 436 is formed, the first contact hole 436 is filled with a metal such as tungsten, and after that, the surface of the interlayer insulating layer 43 is formed as a continuous plane by chemical mechanical polishing or the like. As a result, the light shielding wall 53 is formed as a plug, and the surface of the light shielding wall 53 (plug) forms a plane that is continuous with the surface of the interlayer insulating layer 43.

As illustrated in FIG. 17, FIG. 18, and FIG. 21, between the layer between the gate electrode 33a and the scanning line 3a (the interlayer insulating layer 42 and the interlayer insulating layer 43), the conductive first light shielding layer 4a is formed so as to overlap in a planar manner with the low concentration impurity region 31d2 of the semiconductor layer 31a. The first light shielding layer 4a is formed of a conductive film which has light shielding property such as a conductive polysilicon film, a metal silicide film, a metal film, and a metal compound film.

Between the interlayer insulating layer 45 and the interlayer insulating layer 46, a second light shielding layer 8g overlapping in a planar manner with the first light shielding layer 4a, and a relay electrode 8d overlapping in a planar manner at the end portion of the first region 31d of the semiconductor layer 31a and relay electrodes 8s overlapping in a planar manner at the ends of the second region 31s of the semiconductor layer 31a, and the relay electrodes 8e that are separated from the second light shielding layer 8g on the other side X2 in the X-axis direction are formed by the same conductive material. The second light shielding layer 8g is formed of a conductive film which has light shielding property such as a conductive polysilicon film, a metal silicide film, a metal film, and a metal compound film. The relay electrode 8d is electrically coupled to relay electrode 3d through contact hole 452 that passes through the interlayer insulating layer 45, and the relay electrode 8s is electrically coupled to relay electrode 3s through contact hole 451 that passes through the interlayer insulating layer 45.

In the present embodiment, the second light shielding layer 8g is applied with a constant potential and is electrically coupled to the first light shielding layer 4a via a light shielding portion 51, which will be described later. Therefore, a constant potential is applied to the first light shielding layer 4a via the second light shielding layer 8g. In the present embodiment, a common potential Vcom is applied to the second light shielding layer 8g as a constant potential, and thus the common potential Vcom is applied to the first light shielding layer 4a as a constant potential.

On the side of the semiconductor layer 31a than the second light shielding layer 8g, a light shielding portion 51 electrically coupled with the first light shielding layer 4a is formed, and the light shielding portion 51 covers in a planar manner with a part of the semiconductor layer 31a. More specifically, the light shielding portion 51 includes a first portion 511 that overlaps with the first light shielding layer 4a and a second portion 512 that protrudes toward the side of the semiconductor layer 31a from the first portion 511, wherein the first light shielding layer 4a overlaps in a planar manner with the low concentration impurity region 31d2, and the second portion 512 is disposed on the both sides in the width direction of the low concentration impurity region 31d2 along the low concentration impurity region 31d2.

More specifically, between the first light shielding layer 4a and the second light shielding layer 8g, a second contact hole 455 that extends through the second insulating layer (interlayer insulating layer 43, 45) covering the first light shielding layer 4a is formed, and a first portion 511 of the light shielding portion 51 is positioned inside the first hole portion 455a that overlaps with the first light shielding layer 4a in a planar manner in the second contact hole 455. Accordingly, the first portion 511 electrically couples the first light shielding layer 4a and the second light shielding layer 8g, in a state overlapping with the first light shielding layer 4a from the opposite side of the transistor 30.

The second contact hole 455 includes a pair of second hole portions 455b protruding toward both sides in the width direction of the semiconductor layer 31a from the first hole portion 455a on the side the end portion of the first light shielding layer 4a, and a second portion 512 of the light shielding portion 51 is positioned inside each of the pair of second hole portions 455b. Therefore, the second portion 512 protrudes toward both sides in the width direction of the semiconductor layer 31a on the side of the end portion of the first light shielding layer 4a, and covers the low concentration impurity region 31d2 from both sides in the width direction. The second portion 512 reaches at least the gate insulating layer 32. In the present embodiment, the second portion 512 reaches the interlayer insulating layer 41 positioned in the lower layer of the semiconductor layer 31a. The second portion 512 is in contact with the side surface of the end portion of the first light shielding layer 4a.

In the present embodiment, the first hole portion 455a of the second contact hole 455 overlaps in a planar manner at the end portion on the side of the channel region 31g of the first light shielding layer 4a, and the second hole portion 455b extends in a planar manner toward the first region 31d along both side surfaces in the channel width direction (X-axis direction) of the first light shielding layer 4a. Accordingly, the first portion 511 of the light shielding portion 51 overlaps in a planar manner on the end portion of the first light shielding layer 4a on the channel region 31g side, and the second portion 512 extends in the first region 31d along both sides in the channel width direction (X-axis direction) of the first light shielding layer 4a, and covers the low concentration impurity region 31d2 from both sides in the width direction.

To achieve such a configuration, in the present embodiment, after the second contact hole 455 is formed, the second contact hole 455 is filled with a metal such as tungsten, and after that, the surface of the interlayer insulating layer 45 is formed as a continuous plane by chemical mechanical polishing or the like. As a result, the light shielding portion 51 is formed as a plug, and the surface of the light shielding portion 51 (plug) configures a plane that is continuous with the surface of the interlayer insulating layer 45. Note that the first portion 511 of the light shielding portion 51 overlaps the end portion of the first light shielding layer 4a on the opposite side of the channel region 31g side, and the second portion 512 may be extends toward the second region 31s along both side surfaces in the channel width direction (X-axis direction) of the first light shielding layer 4a.

As illustrated in FIG. 17, FIG. 18, and FIG. 22, in the interlayer insulating layer 46, a through hole 464 exposing the second light shielding layer 8g at the bottom is formed. Inside the through hole 464, on the surface of the interlayer insulating layer 46 outside the through hole 464 on opposite side of the transistor 30, the first capacitor electrode 551 of a holding capacitor 55 is formed, and the first capacitor electrode 551 is electrically coupled to the second light shielding layer 8g at the bottom of the through hole 464. A first dielectric layer 556 and a second capacitor electrode 552 are sequentially stacked on the opposite side of the transistor 30 with respect to the first capacitor electrode 551. The second capacitor electrode 552 is electrically coupled to the relay electrode 8e through a contact hole 463 that passes through the interlayer insulating layer 46, and is electrically coupled to the relay electrode 8d through a contact hole 462 that passes through the interlayer insulating layer 46.

As illustrated in FIG. 17, FIG. 18, and FIG. 23, a second dielectric layer 557 and a third capacitor electrode 553 are sequentially stacked on the opposite side of the transistor 30 with respect to the second capacitor electrode 552. Here, the first capacitor electrode 551, the first dielectric layer 556, the second capacitor electrode 552, the second dielectric layer 557, and the third capacitor electrode 553 overlap the entire bottom and side walls of the through hole 464. The first capacitor electrode 551, the second capacitor electrode 552, and the third capacitor electrode 553 are formed of a conductive films which have light shielding property such as a conductive polysilicon film, a metal silicide film, a metal film, and a metal compound film.

As illustrated in FIG. 17, FIG. 18, and FIG. 24, between the interlayer insulating layer 47 and the interlayer insulating layer 48, a data line 6a that extends in the Y-axis direction so as to overlap with the second inter-pixel region 9c, and the relay electrode 6g separated from the one side X1 in the X-axis direction with respect to the data lines 6a are formed by the same conductive material. The data line 6a is formed of a conductive film which has light shielding property such as a conductive polysilicon film, a metal silicide film, a metal film, and a metal compound film.

The data line 6a is electrically coupled to the relay electrode 8s through a contact hole 471 that passes through the interlayer insulating layers 46, 47. Accordingly, the data line 6a electrically couples to the high concentration impurity region 31s1 of the semiconductor layer 31a via the relay electrodes 8s, 3s, and applies an image signal to the second region 31s.

The relay electrode 6d is electrically coupled to the relay electrode 8e through a contact hole 472 that passes through the interlayer insulating layers 46 and 47. The relay electrode 6g is electrically coupled to the second light shielding layer 8g through a contact hole 475 that passes through the interlayer insulating layer 47, and is electrically coupled to the third capacitor electrode 553 through a contact hole 476 that passes through the interlayer insulating layer 47.

As illustrated in FIG. 17, FIG. 18, and FIG. 25, between the interlayer insulating layer 48 and the interlayer insulating layer 49, a capacitor line 7a that extends in the Y-axis direction so as to overlap with the second inter-pixel region 9c, and the relay electrode 7d separated from the other side X2 in the X-axis direction with respect to the capacitor line 7a are formed by the same conductive material. The capacitance line 7a includes a conductive film which has light shielding property, such as a conductive polysilicon film, a metal silicide film, a metal film, or a metal compound film.

The capacitor line 7a is electrically coupled to the relay electrode 6g through a contact hole 485 that passes through the interlayer insulating layer 48. Accordingly, the capacitor line 7a is electrically coupled to the second light shielding layer 8g via the relay electrode 6g, and a common potential Vcom is applied to the second light shielding layer 8g. The capacitor line 7a is electrically coupled to the third capacitor electrode 553 via the relay electrode 6g, and a common potential Vcom is applied to the third capacitor electrode 553. On the other side, the relay electrode 7d is electrically coupled to the relay electrode 6d through a contact hole 482 that passes through the interlayer insulating layer 48.

A pixel electrode 9a is formed on the surface of the interlayer insulating layer 49 on the opposite side of the transistor 30, and the pixel electrode 9a is electrically coupled to the relay electrode 7d through a contact hole 492 that passes through the interlayer insulating layer 49.

Accordingly, the pixel electrode 9a is electrically coupled to the second capacitor electrode 552 via the relay electrodes 7d, 6d, and 8e, and the pixel electrode 9a is further electrically coupled to the high concentration impurity region 31d1 of the semiconductor layer 31a via the second capacitor electrode 552 and the relay electrodes 8d, 3d. Accordingly, when the transistor 30 is on, the image signal supplied from the data line 6a is electrically coupled to the second capacitor electrode 552 and the pixel electrode 9a of the retention capacitor 55.

In the present embodiment as well, similar to the first embodiment, the holding capacitor 55 is configured so that the capacitive element between the second capacitor electrode 552 and the first capacitor electrode 551 and the capacitive element between the second capacitor electrode 552 and the third capacitor electrode 553 are electrically coupled in parallel. In addition, the first capacitor electrode 551, the first dielectric layer 556, the second capacitor electrode 552, the second dielectric layer 557, and the third capacitor electrode 553 overlap each other at the entire bottom and side walls of the through hole 464, and have a wide opposing surface area. As a result, the electrostatic capacitance of the holding capacity 55 is large.

As described above, in the electro-optical device 100 according to the present embodiment, the scanning line 3a is electrically coupled to the gate electrode 33a through the first contact hole 436 of the first insulating layer (interlayer insulating layer 42, 43) covering the transistor 30 and a first light shielding layer 4a to which a constant potential (Vcom) is applied is disposed in the layer between the gate electrode 33a and the scanning line 3a (between the interlayer insulating layer 42 and the interlayer insulating layer 43). A light shielding portion 51 electrically coupled to the first light shielding layer 4a covers a portion of the semiconductor layer 31a (low concentration impurity region 31d2). Thus, even when light incident from the side of the pixel electrode 9a or the diffraction light thereof is to travel toward the low concentration impurity region 31d2 of the semiconductor layer 31a, such light is shielded by the first light shielding layer 4a and the light shielding portion 51, therefore, operation defects and the like due to photocurrent are unlikely to occur in the transistor 30. In addition, the first light shielding layer 4a and the light shielding portion 51 apply a constant potential (Vcom) on the side of the semiconductor layer 31a than the scanning line 3a, the effect of the potential of the scanning line 3a is less likely to be applied to the transistor 30.

In addition, the first light shielding layer 4a is disposed so as to overlap with a part of the semiconductor layer 31a (the low concentration impurity region 31d2) in a planar manner, and the light shielding portion 51 is disposed in a region of the interlayer insulating layer 43, 45 that overlaps with the first light shielding layer 4a in a planar manner, and inside the second contact hole 455 formed in a region protruding from the first light shielding layer 4a. Thus, the second contact hole 455 includes a first hole portion 455a positioned between the first light shielding layer 4a and the second light shielding layer 8g, and a second hole portion 455b protruding from the first hole portion 455a to the semiconductor layer 31a side, and the light shielding portion 51 includes a first portion 511 that overlaps with the first light shielding layer 4a, and a second portion 512 that protrudes toward the semiconductor layer 31a from the first portion 511. Therefore, the low concentration impurity regions 31d2 of the semiconductor layer 31a can be covered over a wide range by the first light shielding layer 4a and the light shielding portion 51. Thus, even when light incident from the side of the pixel electrode 9a or the diffracted light thereof travels toward the semiconductor layer 31a, the light is shielded by the first light shielding layer 4a and the light shielding portion 50, therefore, operation defects and the like due to photocurrent are less likely to occur in the transistor 30.

Furthermore, when forming the second contact hole 455, the first light shielding layer 4a functions as an etching stopper, so the semiconductor layer 31a is less likely to be damaged by etching. Thus, the second hole 455b of the second contact hole 455 and the second portion 512 of the light shielding portion 51 can be disposed in the vicinity of the low concentration impurity region 31d2. Further, a constant potential can be supplied to the first light shielding layer 4a from the opposite side of the transistor 30. In addition, the constant potential supplying with respect to the first light shielding layer 4a and a light shielding with respect to the semiconductor layer 31a can be performed by the light shielding portion 51.

In addition, a fourth light shielding layer 2a that overlaps with the semiconductor layer 31a via a third insulating layer (interlayer insulating layer 41) on the opposite side of the gate electrode 33a, and the fourth light shielding layer 2a is electrically coupled to the gate electrode 33a via the light shielding wall 53. Thus, the fourth light shielding layer 2a functions as a back gate, and even when the light emitted from the first substrate 19 is incident on the semiconductor layer 31a from the side of the first substrate 19 as return light, the light can be shielded by the fourth light shielding layer 2a and the second wall 532, 533 of the light shielding wall 53.

Furthermore, a retention capacitor 55 is formed in a region overlapping the first light shielding layer 4a from the opposite side of the transistor 30. Thus, even when light incident from the side of the pixel electrode 9a or the diffracted light thereof is to travel toward the semiconductor layer 31a, such light can be shielded by the retention capacitor 55.

### OTHER EMBODIMENTS

In the embodiment described above, in the electrically coupling of first contact hole 436, 445 and the second contact hole 435, 455, a structure is adopted that a plug is disposed inside the first contact holes 436, 445 and the second contact holes 435, 455, a conductive film on the upper layer side is electrically coupled to the conductive film on the lower layer side via a plug, however, a structure may be adopted that the conductive film on the upper layer side is in contact with the conductive film on the lower layer side inside the contact hole.

In addition, in the embodiment described above, in the contact holes 431, 432, 441, 442, 451, 452, 462, 463, 471, 472, 473, 474, 475, 476, 482, 483, 484, 485, 492 as well, an electrically coupling is performed by the plug, but a structure may be adopted in part or all of the contact hole, in which the conductive film on the upper layer side is in contact with the conductive film on the lower layer side inside the contact hole.

In the above embodiment, although description is given in which the transistor 30 has the LDD structure, it is may also be applied when an offset gate structure in which the high concentration impurity regions 31d1, 31s1 are separated from the end portion of the gate electrode 33a. In this case, regions where impurities are not introduced between the high concentration impurity regions 31d1, 31s1 and the ends of the gate electrode 33a become low concentration impurity regions 31d2, 31s2.

### Installation Example to Electronic Apparatus

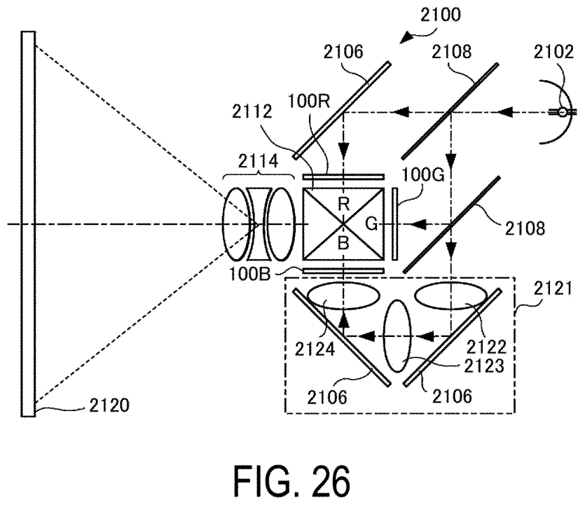

An electronic apparatus using the electro-optical device 100 according to the above-described exemplary embodiments will be described below. FIG. 26 is a schematic configuration diagram illustrating a projection-type display device employing the electro-optical device 100 to which the invention is applied. An illustration of an optical element such as a polarizing plate is omitted in FIG. 26. A projection-type display device 2100 illustrated in FIG. 26 is an example of the electronic apparatus employing the electro-optical device 100.

The projection-type display device 2100 illustrated in FIG. 26, in which the electro-optical device 100 according to the embodiment described before is used as a light valve, can conduct high-definition and bright display without making the apparatus large. Inside the projection-type display device 2100 illustrated in FIG. 26, a lamp unit 2102 (light source unit) with a white light source such as a halogen lamp is provided with. Projection light emitted from the lamp unit 2102 is split into three primary colors of R (red), G (green), and B (blue) by three mirrors 2106 and two dichroic mirrors 2108 installed inside. The split projection light is guided to light valves 100R, 100G, and 100B corresponding to the primary colors, respectively and modulated. Note that since the light of the B color has a long optical path as compared to the other light of the R color and the G color, the light of the B color is guided via a relay lens system 2121 including an incidence lens 2122, a relay lens 2123, and an emission lens 2124 to prevent a loss due to the long optical path of the light of the B color.

The light modulated by each of the light valves 100R, 100G, and 100B is incident on a dichroic prism 2112 from three directions. Then, at the dichroic prism 2112, the light of the R color and the light of the B color are reflected at 90 degrees, and the light of the G color is transmitted. Accordingly, an image of the primary colors are synthesized, and subsequently a color image is projected on a screen 2120 by a projection lens group 2114 (projection optical system).

Other Projection-Type Display Devices

Note that the projection-type display device may include a configuration in which an LED light source or the like configured to emit light of each color is used as a light source unit and the light of each color emitted from the LED light source is supplied to another liquid-crystal device.

Other Electronic Apparatuses

The electronic apparatus including the electro-optical device 100 to which the present disclosure is applied is not limited to the projection-type display device 2100 of the above-described exemplary embodiment. Examples of the electronic apparatus may include a projection-type head up display (HUD), a direct-view-type head mounted display (HMD), a personal computer, a digital still camera, and a liquid crystal television.

What is claimed is:

1. A electro-optical device, comprising:
a transistor having a gate electrode and a semiconductor layer;
a first insulating layer covering the transistor and having a first contact hole;
a scanning line electrically connected to the gate electrode through the first contact hole;
a first light shielding layer that is disposed at a layer between the gate electrode and the scanning line and to which a constant potential is applied; and
a light shielding portion that is disposed to cover a part of the semiconductor layer and that is electrically connected to the first light shielding layer.

2. The electro-optical device according to claim 1, wherein
the first light shielding layer is disposed to overlap with the part of the semiconductor layer in plan view, and
the light shielding portion includes a first portion overlapping the first light shielding layer and a second portion protruding from the first portion to the semiconductor layer side.

3. The electro-optical device according to claim 2, wherein
the first portion overlaps the first light shielding layer on an opposite side thereof from the transistor, and
the second portion protrudes toward the semiconductor layer side beside the first light shielding layer.

4. The electro-optical device according to claim 3, comprising:
a pixel electrode electrically connected to the transistor, wherein
the semiconductor layer includes a channel region, a high concentration impurity region electrically connected to the pixel electrode, and a low concentration impurity region between the channel region and the high concentration impurity region, and the light shielding portion is disposed to cover the low concentration impurity region as the part of the semiconductor layer.

5. The electro-optical device according to claim 1, wherein
the second portion is disposed along the low concentration impurity region on both sides in the width direction of the low concentration impurity region.

6. The electro-optical device according to claim 3, comprising:
a second insulating layer overlapping the first light shielding layer and having a second contact hole; and
a second light shielding layer electrically connected with the first light shielding layer through the second contact hole, wherein
the second contact hole includes a first hole portion extending through the second insulating layer between the first light shielding layer and the second light shielding layer, and a second hole portion protruding, beside the first light shielding layer, toward the semiconductor layer side from the first hole, and
a portion of the light shielding portion located inside the first hole portion is the first portion, and a portion of the light shielding portion located inside the second hole portion is the second portion.

7. The electro-optical device according to claim 2, comprising:
a third light shielding layer disposed on an opposite side from the first light shielding layer with respect to the transistor, wherein
the third light shielding layer is electrically connected to the first light shielding layer through the second portion.

8. The electro-optical device according to claim 1, comprising:
a fourth light shielding layer overlapping the semiconductor layer on an opposite side thereof from the gate electrode, with a third insulating layer interposed between the semiconductor layer and the forth light shielding layer, wherein
the gate electrode and the fourth light shielding layer are electrically connected.

9. The electro-optical device according to claim 1, comprising:
a holding capacitor overlapping the first light shielding layer on an opposite side thereof from the gate electrode.

10. An electronic apparatus comprising the electro-optical device according to claim 1.
